(19) United States
(12) Patent Application Publication
(10) Pub. No.: US 2025/0230539 A1
(43) Pub. Date: Jul. 17, 2025

(54) METHOD FOR MANUFACTURING MODIFIED SUBSTRATE AND METHOD FOR MANUFACTURING SEMICONDUCTOR DEVICE

(71) Applicant: FUJIFILM CORPORATION, Tokyo (JP)

(72) Inventors: Akihiro Hakamata, Shizuoka (JP); Naoya Shimoju, Shizuoka (JP); Koichi Sato, Shizuoka (JP); Atsushi Mizutani, Shizuoka (JP)

(21) Appl. No.: 19/097,215

(22) Filed: Apr. 1, 2025

Related U.S. Application Data
(63) Continuation of application No. PCT/JP2023/040717, filed on Nov. 13, 2023.

(30) Foreign Application Priority Data
Nov. 17, 2022 (JP) 2022-184298
Jan. 17, 2023 (JP) 2023-005431
Sep. 19, 2023 (JP) 2023-150969

(51) Int. Cl. C23C 16/04; C23C 16/40; C23C 16/455; H01L 21/02

(52) U.S. Cl. CPC C23C 16/04; C23C 16/403; C23C 16/45525; H01L 21/0228; H01L 21/02178

(57) ABSTRACT

The present invention provides a method for producing a modified substrate, the method making it possible to produce a modified substrate in which an ALD coating film is formed in a predetermined region with good selectivity by performing an ALD treatment, and a method for producing a semiconductor device, the method involving the method for producing a modified substrate. The method for producing a modified substrate of an embodiment of the present invention includes a step 1 of bringing a substrate having at least two surfaces of a first surface and a second surface, which are composed of materials different from each other, into contact with a chemical liquid including a compound which has a functional group bonded to or adsorbed on the first surface, and a crosslinkable group, and has a molecular weight of 500 or less, and a solvent, to form a first coating film on the first surface; and a step 2 of subjecting the substrate obtained in the step 1 to an atomic layer deposition treatment to form a second coating film on the second surface.

### CROSS-REFERENCE TO RELATED APPLICATIONS

This application is a Continuation of PCT International. Application No. PCT/JP2023/040717 filed on Nov. 13, 2023, which claims priority under 35 U.S.C. § 119 (a) to Japanese Patent Application No. 2022-184298 filed on Nov. 17, 2022, Japanese Patent Application No. 2023-005431 filed on Jan. 17, 2023, and Japanese Patent Application No. 2023-150969 filed on Sep. 19, 2023. The above applications are hereby expressly incorporated by reference, in their entirety, into the present application.

### BACKGROUND OF THE INVENTION

### 1. Field of the Invention

The present invention relates to a method for producing a modified substrate and a method for producing a semiconductor device.

### 2. Description of the Related Art

With the further miniaturization of semiconductor devices, there is a demand for the formation of finer and more precise semiconductor elements. In the related art, photolithography has been used in the formation of a semiconductor element, but it requires registration of patterns or the like and is no longer capable of meeting the accuracy required these days.

Currently, atomic layer deposition (ALD) is known as a technique for forming a film in a predetermined region. As a related technique using such ALD, Wanxing Xu, Mitchel G. N. Haeve, Paul C. Lemaire, Kashish Sharma, Dennis M. Hausmann, and Sumit Agarwal, Langmuir 2022, 38, 2, 652-660 reported that by absorbing a low-molecular-weight aminosilane compound on a silicon dioxide surface of a substrate as an inhibitor, and then an aluminum oxide layer is formed by atomic layer deposition using dimethylaluminum isopropoxide and water as precursors, whereby the growth of the aluminum oxide layer is inhibited in a region where the low-molecular-weight aminosilane is adsorbed.

### SUMMARY OF THE INVENTION

On the other hand, in recent years, studies have been conducted on a method for forming a film (modified film) by modifying one region of a substrate having a plurality of regions (for example, a metal region including metal atoms and an insulating region including an insulator) consisting of different materials on the surface, and then performing an ALD treatment, whereby a coating film with ALD (ALD coating film) is not formed in a region where the modified film is not formed, and the ALD coating film is formed in a region where the modified film is formed, thereby forming a fine pattern.

As a result of studying the technique described in Wanxing Xu, Mitchel G. N. Haeve, Paul C. Lemaire, Kashish Sharma, Dennis M. Hausmann, and Sumit Agarwal, Langmuir 2022, 38, 2, 652-660, the present inventors have attempted to form an ALD coating film on a region where a modified film was not formed after forming the modified film using a low-molecular-weight aminosilane compound, and as a result, a thick ALD coating film was formed even on a region where the modified film was formed (on the modified film). That is, it was difficult to form an ALD coating film with good selectivity in a region where the modified film was not formed.

Therefore, an object of the present invention is to provide a method for producing a modified substrate, the method making it possible to produce a modified substrate in which an ALD coating film is formed in a predetermined region with good selectivity by performing an ALD treatment; and a method for producing a semiconductor device, the method involving the method for producing a modified substrate.

The present inventors have conducted extensive studies to accomplish the object, and as a result, have completed the present invention. That is, the present inventors have found that the object can be accomplished by the following configurations.
[1] A method for producing a modified substrate, the method comprising:
a step 1 of bringing a substrate having at least two surfaces of a first surface and a second surface, which are composed of materials different from each other, into contact with a chemical liquid including a compound which has a functional group bonded to or adsorbed on the first surface, and a crosslinkable group, and has a molecular weight of 500 or less, and a solvent, to form a first coating film on the first surface; and
a step 2 of subjecting the substrate obtained in the step 1 to an atomic layer deposition treatment to form a second coating film on the second surface.
[2] The method for producing a modified substrate according to [1],
in which the functional group bonded to or adsorbed on the first surface is selected from the group consisting of a nitrogen-containing group, a phosphonic acid group or a salt thereof, a phosphonic acid ester, a phosphoric acid group or a salt thereof, a carboxy group or a salt thereof, a hydroxy group, a thiol group, and a hydrolyzable silyl group.
[3] The method for producing a modified substrate according to [1] or [2],
in which the crosslinkable group is an ethylenically unsaturated group.
[4] The method for producing a modified substrate according to any one of [1] to [3],
in which the crosslinkable group is selected from the group consisting of an acryloyl group, a methacryloyl group, a vinyl ether group, a styryl group, a vinylnaphthyl group, and a vinyl group.
[5] A method for producing a modified substrate, the method comprising:
a step 1 of bringing a substrate having at least two surfaces of a first surface and a second surface, which are composed of materials different from each other, into contact with a chemical liquid including a compound which has a group selected from the group consisting of a nitrogen-containing group, a phosphonic acid group or a salt thereof, a phosphonic acid ester, a phosphoric acid group or a salt thereof, a carboxy group or a salt thereof, a hydroxy group, a thiol group, and a hydrolyzable silyl group, and a crosslinkable group, and has a molecular weight of 500 or less, and a solvent, to form a first coating film on the first surface; and
a step 2 of subjecting the substrate obtained in the step 1 to an atomic layer deposition treatment to form a second coating film on the second surface.
[6] The method for producing a modified substrate according to [5],
in which the crosslinkable group is an ethylenically unsaturated group.
[7] The method for producing a modified substrate according to [5] or [6],
in which the crosslinkable group is selected from the group consisting of an acryloyl group, a methacryloyl group, a vinyl ether group, a styryl group, a vinylnaphthyl group, and a vinyl group.
[8] The method for producing a modified substrate according to any one of [1] to [7],
in which at least one of the first surface or the second surface is a metal surface composed of a metal.
[9] The method for producing a modified substrate according to any one of [1] to [8],
in which at least one of the first surface or the second surface includes at least one metal atom selected from the group consisting of a copper atom, a cobalt atom, a titanium atom, a tantalum atom, a tungsten atom, a ruthenium atom, and a molybdenum atom.
[10] The method for producing a modified substrate according to any one of [1] to [9],
in which at least one of the first surface or the second surface includes at least one metal atom selected from the group consisting of a titanium atom, a tungsten atom, a ruthenium atom, and a molybdenum atom.
[11] The method for producing a modified substrate according to any one of [1] to [10],
in which the second coating film is a metal film or a metal oxide film.
[12] The method for producing a modified substrate according to any one of [1] to [11], the method further comprising:
a step 3 of removing the first coating film after the step 2.
[13] The method for producing a modified substrate according to any one of [1] to [4] and [8] to [12],
in which the chemical liquid includes a polymerization inhibitor.
[14] The method for producing a modified substrate according to [13],
in which the polymerization inhibitor includes at least one compound selected from the group consisting of a phenol-based compound, a quinone-based compound, a free radical-based compound, an amine-based compound, and a phosphine-based compound.
[15] The method for producing a modified substrate according to [13] or [14],
in which a content of the polymerization inhibitor is 0.001 to 1.000 part by mass with respect to 100 parts by mass of the compound.
[16] The method for producing a modified substrate according to [13] or [14],
in which a content of the polymerization inhibitor is 0.01 parts by mass or more with respect to 100 parts by mass of the compound.
[17] The method for producing a modified substrate according to any one of [5] to [7],
in which the chemical liquid includes a polymerization inhibitor.
[18] The method for producing a modified substrate according to [17],
in which the polymerization inhibitor includes at least one compound selected from the group consisting of a phenol-based compound, a quinone-based compound, a free radical-based compound, an amine-based compound, and a phosphine-based compound.
[19] The method for producing a modified substrate according to [17] or [18], in which a content of the polymerization inhibitor is 0.001 to 1.000 part by mass with respect to 100 parts by mass of the compound.
[20] The method for producing a modified substrate according to [17] or [18],
in which a content of the polymerization inhibitor is 0.01 parts by mass or more with respect to 100 parts by mass of the compound.
[21] The method for producing a modified substrate according to any one of [1] to [20],
in which the chemical liquid includes water.
[22] The method for producing a modified substrate according to [21],
in which a content of the water is 80% by mass or less with respect to a total mass of the solvent.
[23] The method for producing a modified substrate according to any one of [1] to [22],
in which the chemical liquid includes three or more kinds of the solvents.
[24] A method for producing a semiconductor device, the method comprising:
the method for producing a modified substrate according to any one of [1] to [23].

According to the present invention, it is possible to provide a method for producing a modified substrate, the method making it possible to produce a modified substrate in which an ALD coating film is formed in a predetermined region with good selectivity by performing an ALD treatment; and a method for producing a semiconductor device, the method involving the method for producing a modified substrate.

### DESCRIPTION OF THE PREFERRED EMBODIMENTS

Hereinafter, the same meanings are used in the present specification.

In the present specification, a numerical range represented by “to” means a range including numerical values before and after “to” as a lower limit value and an upper limit value.

A compound described in the present specification may include a structural isomer, an optical isomer, and an isotope unless otherwise specified. In addition, one kind of structural isomer, optical isomer, and isotope alone, or two or more kinds thereof may be included.

In the present specification, with regard to the bonding direction of a divalent group (for example, —COO—), unless otherwise specified, in a case where Y in a compound represented by “X—Y—Z” is —COO—, the compound may be either “X—O—CO—Z” or “X—CO—O—Z”.

In the present specification, unless otherwise specified, a molecular weight of a compound having a molecular weight distribution is a weight-average molecular weight.

Hereinafter, the method for producing a modified substrate of an embodiment of the present invention will be described in detail.

A first embodiment of the method for producing a modified substrate of the embodiment of the present invention is a method for producing a modified substrate, the method including: a step 1 of bringing a substrate having at least two surfaces of a first surface and a second surface, which are composed of materials different from each other, into contact with a chemical liquid including a compound (hereinafter also referred to as a “specific compound 1”) which has a functional group bonded to or adsorbed on the first surface, and a crosslinkable group, and has a molecular weight of 500 or less, and a solvent, to form a first coating film on the first surface; and a step 2 of subjecting the substrate obtained in the step 1 to an atomic layer deposition treatment to form a second coating film on the second surface.

In addition, a second embodiment of the method for producing a modified substrate of the embodiment of the present invention is a method for producing a modified substrate, the method including a step 1 of bringing a substrate having at least two surfaces of a first surface and a second surface, which are composed of materials different from each other, into contact with a chemical liquid including a compound (hereinafter also referred to as a “specific compound 2”) which has a group (hereinafter also referred to as a “specific group”) selected from the group consisting of a nitrogen-containing group, a phosphonic acid group or a salt thereof, a phosphonic acid ester, a phosphoric acid group or a salt thereof, a carboxy group or a salt thereof, a hydroxy group, a thiol group, and a hydrolyzable silyl group, and a crosslinkable group, and has a molecular weight of 500 or less, and a solvent, to form a first coating film on the first surface; and a step 2 of subjecting the substrate obtained in the step 1 to an atomic layer deposition treatment to form a second coating film on the second surface.

The mechanism by which the object of the present invention can be accomplished by adopting the configurations for the methods for producing a modified substrate of the embodiments of the present invention (the first embodiment and the second embodiment) is not necessarily clear, but is presumed to be as follows by the present inventors.

Furthermore, the mechanism by which the effect is obtained is not limited by the following supposition. In other words, even in a case where an effect is obtained by a mechanism other than the following, it is included in the scope of the present invention.

By configuring the chemical liquid used in the method for producing a modified substrate of the embodiment of the present invention (hereinafter also referred to as a “main chemical liquid”) to include a specific compound 1 having a functional group bonded to or adsorbed on the first surface or a specific compound 2 having a specific group, the functional group bonded to or adsorbed on the first surface in the specific compound 1 or the specific group in the specific compound 2 is bonded to or adsorbed on the first surface, and as a result, the first coating film is easily formed on the first surface. The first coating film layer includes a component derived from the specific compound 1 or the specific compound 2.

Further, since the specific compound 1 and the specific compound 2 have a crosslinkable group, the crosslinkable groups react with each other by heating the substrate in the ALD treatment in the step 2 performed after the step 1, whereby a covalent bond is formed and the first coating film serves as a cured film.

Therefore, it is presumed that by configuring the first coating film to be uniformly formed on the first surface and configuring the crosslinkable groups to be covalently bonded to each other in the ALD treatment, a cured film having excellent heat resistance and water repellency is formed on the first surface. Therefore, the ALD coating film is hardly formed on the cured film in the ALD treatment, and as a result, the ALD coating film is easily formed on the second surface with good selectivity.

Hereinafter, each step that can be included in the method for producing a modified substrate of the embodiment of the present invention will be described in detail.

In addition, a fact that the ALD treatment is performed and the selectivity with which the ALD coating film is formed in a predetermined region is more excellent is also referred to as “the effect of the present invention being more excellent”.

### [Method for Producing Modified Substrate (First Embodiment)]

The first embodiment of the method for producing a modified substrate of the embodiment of the present invention includes a step 1.

The step 1 is a step of bringing a substrate having at least two surfaces of a first surface and a second surface, which are composed of materials different from each other, into contact with a chemical liquid (hereinafter also referred to as a “chemical liquid 1”) including a compound (specific compound 1) which has a functional group bonded to or adsorbed on the first surface, and a crosslinkable group, and has a molecular weight of 500 or less, and a solvent, to form a first coating film on the first surface.

Hereinafter, the chemical liquid 1 used in the step 1 will be described in detail.

### <Chemical Liquid 1>

The chemical liquid 1 includes the specific compound 1 and a solvent.

### (Specific Compound 1)

As described above, the specific compound 1 is a compound which has a functional group bonded to or adsorbed on the first surface and a crosslinkable group, and has a molecular weight of 500 or less.

The functional group bonded to or adsorbed on the first surface may form any bond or interaction such as a covalent bond, a coordinate bond, an ionic bond, a hydrogen bond, a Van der Waals bond, and a metal bond with the first surface.

As will be described later, from the viewpoint that the first surface preferably includes a metal atom, it is preferable that the functional group bonded to or adsorbed on the first surface is a functional group bonded to or adsorbed on a surface including a metal atom.

Examples of the functional group bonded to or adsorbed on the first surface include a nitrogen-containing group, a phosphonic acid ester, a phosphoric acid group (—PO₄H₂) or a salt thereof, a phosphonic acid group (—PO₃H₂) or a salt thereof, a sulfo group (—SO₃H) or a salt thereof, a carboxy group (—COOH) or a salt thereof, a hydroxy group (—OH), a thiol group (—SH), and a hydrolyzable silyl group.

In a case where the specific compound 1 includes a nitrogen-containing group, a phosphonic acid ester, a phosphoric acid group (—PO₄H₂) or a salt thereof, a phosphonic acid group (—PO₃H₂) or a salt thereof, a sulfo group (—SO₃H) or a salt thereof, a carboxy group (—COOH) or a salt thereof, a hydroxy group (—OH), or a thiol group (—SH), it is easy to more selectively form the first coating film on a substrate of an aspect A which will be described later, and in a case where the specific compound 1 includes a hydrolyzable silyl group, it is easy to more selectively form the first coating film on a substrate of an aspect B (in particular, an aspect B3) which will be described later.

Among those, as the functional group bonded to or adsorbed on the first surface, a group selected from the group consisting of a nitrogen-containing group, a phosphonic acid group or a salt thereof, a phosphonic acid ester, a phosphoric acid group or a salt thereof, a carboxy group or a salt thereof, a hydroxy group, a thiol group, and a hydrolyzable silyl group is preferable, a group selected from the group consisting of the nitrogen-containing group, the phosphonic acid group or a salt thereof, the phosphonic acid ester, the carboxy group or a salt thereof, the hydroxy group, the thiol group, and the hydrolyzable silyl group is more preferable, and a group selected from the group consisting of the nitrogen-containing group, the phosphonic acid group or a salt thereof, and the phosphonic acid ester is still more preferable.

Examples of the nitrogen-containing group include a primary amino group (—NH₂), a secondary amino group (—NR^{T}H), a tertiary amino group (—NR^{T}₂), and a quaternary ammonium group (—N⁺R^{T}₃), and the nitrogen-containing group is preferably the primary amino group, the secondary amino group, or the tertiary amino group, and more preferably the primary amino group.

Furthermore, R^{T} represents an alkyl group having 1 to 3 carbon atoms and a plurality of R^{T}'s may be different from each other. In addition, a plurality of R^{T}'s may be bonded to each other to form a ring. The ring to be formed is a ring including a nitrogen atom, and examples thereof include a pyrrolidine ring, a piperidine ring, and a piperazine ring.

In addition, the nitrogen-containing group may be a nitrogen-containing heteroaryl group which may be a monocycle or a polycycle. Examples of the nitrogen-containing heteroaryl group include a pyridyl group, a triazine group, a pyrrole group, a pyrazole group, an imidazole group, a triazole group, a benzimidazole group, and a benzotriazole group.

The salt of the phosphoric acid group refers to a group represented by —PO₄²⁻ Ctⁿ⁺_{2/n}. Furthermore, Ctⁿ⁺ represents an n-valent cation, where n represents 1 or 2. Examples of the monovalent cation include Lit, Na⁺, K⁺, and NH₄⁺. In a case where Cⁿ⁺ represents a monovalent cation, the number thereof is 2. Examples of the divalent cation include Mg²⁺ and Ca²⁺. In a case where Ctⁿ⁺ represents a divalent cation, the number thereof is 1.

Furthermore, the compound having a phosphoric acid group is also referred to as a “phosphoric compound” and the functional group name is also referred to as “-phosphoric acid”.

The salt of the phosphonic acid group refers to a group represented by —PO₃²⁻ Cⁿ⁺ 2/n. Ctⁿ⁺ represents an n-valent cation, where n represents 1 or 2. Examples of the monovalent cation and the divalent cation include the same cations as the cations described in the salt of the phosphoric acid group above, and the numbers thereof are also the same.

In addition, the phosphonic acid ester refers to a group represented by —PO₃R^{P}₂. R^{P}'s each independently represent a hydrogen atom or an organic group. It should be noted that at least one of the two existing R^{P}'s represents an organic group. The phosphonic acid ester is preferably a monoester. That is, it is preferable that one of the two existing R^{P}'s is a hydrogen atom and the other is an organic group.

As the organic group, an aliphatic hydrocarbon group having 1 to 10 carbon atoms is preferable, an aliphatic hydrocarbon group having 1 to 6 carbon atoms is more preferable, and an alkyl group having 1 to 6 carbon atoms is still more preferable. The aliphatic hydrocarbon group and the alkyl group may be linear, branched, or cyclic.

Furthermore, the compound having a phosphonic acid group is also referred to as a “phosphonic acid compound”.

The salt of the sulfo group refers to a group represented by —SO₃⁻Ct⁺. Ct⁺ represents a monovalent cation, and examples thereof include the same cations as the monovalent cations described in the salt of the phosphoric acid group.

The salt of the carboxy group refers to a group represented by —COO⁻Ct⁺. Ct⁺ represents a monovalent cation, and examples thereof include the same cations as the monovalent cations described in the salt of the phosphoric acid group.

The hydroxy group may be any of an alcoholic hydroxy group (a hydroxy group bonded to an aliphatic hydrocarbon) or a phenolic hydroxy group (a hydroxy group bonded to an aromatic hydrocarbon), but the alcoholic hydroxy group is preferable.

The hydrolyzable silyl group refers to a group which has a silicon atom and can be converted into a group capable of forming a bond with the first surface by reacting with water. Examples of the hydrolyzable silyl group include an alkoxysilyl group and a chlorosilyl group (a group having an —Si—Cl structure).

In the alkoxysilyl group, the number of alkoxy groups bonded to the silicon atom (Si atom) is not particularly limited, but is preferably 2 or more, and more preferably 3. The number of carbon atoms in the alkoxy group bonded to the Si atom is preferably 1 to 6, and more preferably 1 to 3.

Among these, a trimethoxysilyl group or a triethoxysilyl group is preferable as the alkoxysilyl group.

In the chlorosilyl group, the number of chlorine atoms bonded to the Si atom is preferably 1 to 3, and more preferably 1. In a case where the number of chlorine atoms is 1 or 2, the chlorosilyl group is preferably a dialkyl monochlorosilyl group or a monoalkyl dichlorosilyl group.

The alkyl group may be linear, cyclic, or branched, but is preferably linear. Among these, a methyl group is preferable as the alkyl group.

The number of functional groups contained in the specific compound 1, which are bonded to or adsorbed on the first surface, is not particularly limited as long as it is 1 or more, but the number of functional groups is preferably 1 to 3, and more preferably 1.

The crosslinkable group is not particularly limited as long as a bond can be formed between the crosslinkable groups by heating. Examples of the crosslinkable group include a radically polymerizable group, a cationically polymerizable group, and an anionically polymerizable group, and an ethylenically unsaturated group is preferable.

Among these, as the crosslinkable group, a group selected from the group consisting of an acryloyl group, a methacryloyl group, a vinyl ether group, a styryl group, a vinylnaphthyl group, and a vinyl group is preferable, and the styryl group, the vinylnaphthyl group, or the vinyl group is more preferable. The vinylnaphthyl group is preferably a group obtained by removing a hydrogen atom at the 6-position from 2-vinylnaphthalene.

Furthermore, the vinyl group is a group represented by CH₂═CH—, but in the present specification, the acryloyl group, the methacryloyl group, the vinyl ether group, the styryl group, and the vinylnaphthyl group are all treated as groups different from the vinyl group. That is, a structure represented by CH₂═CH— is included in the acryloyl group, the methacryloyl group, the vinyl ether group, the styryl group, and the vinylnaphthyl group, but is treated as a group different from the vinyl group.

The number of the crosslinkable groups contained in the specific compound 1 is not particularly limited as long as it is 1 or more, but the number of the crosslinkable groups is preferably 1 to 3, and more preferably 1.

The specific compound 1 preferably has a structure exhibiting alignment properties. The structure exhibiting alignment properties refers to a structure having a function of aligning the specific compound 1 in a direction perpendicular to the first surface in a case where the first coating film is formed on the first surface by bringing the substrate into contact with the chemical liquid 1.

The structure exhibiting alignment properties is not particularly limited, and examples thereof include a divalent aliphatic hydrocarbon group which may have an etheric oxygen atom, a divalent aromatic ring group, and a group formed by a combination thereof. Among these, the divalent aliphatic hydrocarbon group which may have an etheric oxygen atom is preferable.

The divalent aliphatic hydrocarbon group may be linear, branched, or cyclic, but is preferably linear. Examples of the divalent aliphatic hydrocarbon group include an alkylene group, an alkenylene group, and an alkynylene group, and the alkylene group is preferable.

The number of carbon atoms in the divalent aliphatic hydrocarbon group is not particularly limited, but is preferably 1 to 25, more preferably 3 to 20, and still more preferably 6 to 18 from the viewpoint of improving the stability of the first coating film on the first surface.

The divalent aromatic ring group may be any of a divalent aromatic hydrocarbon group (arylene group) or a divalent aromatic heterocyclic group (heteroarylene group), but is preferably an arylene group.

The divalent aromatic ring group may be a monocycle or a polycycle.

The number of carbon atoms in the divalent aromatic ring group is preferably 5 to 25, more preferably 6 to 20, and still more preferably 6 to 10.

Examples of the arylene group include a phenylene group.

Examples of the heteroarylene group include a group obtained by removing two hydrogen atoms from pyridine.

Among these, the specific compound 1 is preferably a compound represented by Formula (S1).

X¹-L¹-Y¹ Formula (S1)

In Formula (S1), X¹ represents a group selected from the group consisting of a nitrogen-containing group, a phosphonic acid group or a salt thereof, a phosphonic acid ester, a phosphoric acid group or a salt thereof, a carboxy group or a salt thereof, a hydroxy group, a thiol group, and a hydrolyzable silyl group.

Specific aspects and suitable aspects of each group represented by X¹ are as described above for the functional group bonded to or adsorbed on the first surface. Among these, a primary amino group is preferable as the group represented by X¹.

In Formula (S1), Y¹ represents an ethylenically unsaturated group.

As the ethylenically unsaturated group represented by Y¹, a group selected from the group consisting of an acryloyl group, a methacryloyl group, a vinyl ether group, a styryl group, a vinylnaphthyl group, and a vinyl group is preferable.

In Formula (S1), L¹ represents a divalent aliphatic hydrocarbon group which may have an etheric oxygen atom, a divalent aromatic ring group, or a group formed by a combination thereof.

Specific aspects and suitable aspects of the divalent aliphatic hydrocarbon group, the divalent aromatic ring group, and the group formed by a combination thereof are as described above.

Among these, as the divalent aliphatic hydrocarbon group, an alkylene group which may have an etheric oxygen atom is preferable, and an alkylene group having 6 to 18 carbon atoms, which may have an etheric oxygen atom, is more preferable.

As the divalent aromatic ring group, a phenylene group is preferable.

The molecular weight of the specific compound 1 is not particularly limited as long as it is 500 or less, but the molecular weight is preferably 50 to 450, more preferably 100 to 450, and still more preferably 150 to 400.

The content of the specific compound 1 is preferably 0.0001% to 10.0% by mass, more preferably 0.001% to 1.0% by mass, and still more preferably 0.01% to 0.5% by mass with respect to a total mass of the chemical liquid 1.

Two or more kinds of the specific compounds 1 may be used in combination.

In a case where two or more kinds of the specific compounds 1 are used in combination, a total content thereof is preferably within the range.

### (Solvent)

The chemical liquid 1 includes a solvent.

Examples of the solvent include water and an organic solvent.

Examples of the organic solvent include a hydrocarbon-based solvent, an alcohol-based solvent, a polyol-based solvent, a glycol ether-based solvent, an ether-based solvent, a ketone-based solvent, an amide-based solvent, a sulfur-containing solvent, and an ester-based solvent.

Examples of the hydrocarbon-based solvent include an aliphatic hydrocarbon-based solvent such as n-pentane and n-hexane; an alicyclic hydrocarbon-based solvent such as cyclohexane and methylcyclohexane; and an aromatic hydrocarbon-based solvent such as toluene and xylene.

Examples of the alcohol-based solvent include an aliphatic alcohol-based solvent having 1 to 18 carbon atoms such as methanol, ethanol, 1-propanol, 2-propanol (also referred to as isopropyl alcohol (IPA)), 2-butanol, isobutyl alcohol, tert-butyl alcohol, isopentyl alcohol, and 4-methyl-2-pentanol (also referred to as methyl isobutyl carbinol (MIBC)); an alicyclic alcohol-based solvent having 3 to 18 carbon atoms such as cyclohexanol; an aromatic alcohol-based solvent such as benzyl alcohol; and a ketone alcohol-based solvent such as diacetone alcohol.

The number of carbon atoms in the alcohol-based solvent is preferably 1 to 8, more preferably 2 to 7, and still more preferably 3 to 6.

Examples of the polyol-based solvent include a glycol-based solvent having 2 to 18 carbon atoms.

Examples of the glycol-based solvent include ethylene glycol, propylene glycol (1,2-propanediol), 1,3-propanediol, diethylene glycol, and dipropylene glycol.

Examples of the glycol ether-based solvent include a glycol monoether-based solvent having 3 to 19 carbon atoms.

Examples of the glycol monoether-based solvent include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol monomethyl ether, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

The number of carbon atoms in the glycol ether-based solvent is preferably 1 to 8, more preferably 2 to 7, and still more preferably 3 to 6.

Examples of the ketone-based solvent include acetone, methyl ethyl ketone, methyl isobutyl ketone, and cyclohexanone.

Examples of the ether-based solvent include diethyl ether, diisopropyl ether, dibutyl ether, t-butyl methyl ether, cyclohexyl methyl ether, and tetrahydrofuran.

Examples of the amide-based solvent include formamide, monomethylformamide, dimethylformamide, acetamide, monomethylacetamide, dimethylacetamide, monoethylacetamide, diethylacetamide, and N-methylpyrrolidone.

Examples of the sulfur-containing solvent include dimethyl sulfone, dimethyl sulfoxide, and sulfolane.

Examples of the ester-based solvent include n-butyl acetate, ethyl lactate, propylene glycol acetate, propylene glycol monomethyl ether acetate, γ-butyrolactone, and δ-valerolactone.

The ester-based solvent may be a glycol ester-based solvent, a monocarboxylic acid ester-based solvent such as n-butyl acetate and ethyl lactate, a lactone-based solvent such as γ-butyrolactone (GBL) and δ-valerolactone, or a carbonate-based solvent such as dimethyl carbonate, diethyl carbonate, ethylene carbonate, and propylene carbonate (propylene carbonate).

Examples of the glycol ester-based solvent include glycol dicarboxylate solvents having 6 to 22 carbon atoms, such as ethylene glycol diacetate, diethylene glycol diacetate, triethylene glycol diacetate, tetraethylene glycol diacetate, propylene glycol acetate, propylene glycol diacetate, dipropylene glycol diacetate, and methoxybutyl acetate; and glycol monoether carboxylate-based solvents having 5 to 21 carbon atoms, such as propylene glycol monomethyl ether acetate (PGMEA), ethylene glycol monomethyl ether acetate, ethylene glycol monoethyl ether acetate, ethylene glycol monobutyl ether acetate, diethylene glycol monomethyl ether acetate, diethylene glycol monobutyl ether acetate, triethylene glycol monomethyl ether acetate, tetraethylene glycol monomethyl ether acetate, propylene glycol monoethyl ether acetate, propylene glycol monobutyl ether acetate, dipropylene glycol monomethyl ether acetate, tripropylene glycol monomethyl ether acetate, tetrapropylene glycol monomethyl ether acetate, and butylene glycol monomethyl ether acetate.

The number of carbon atoms in the ester-based solvent is preferably 3 to 22, and more preferably 4 to 12.

Among these, as the solvent, the alcohol-based solvent, the glycol ether-based solvent, or the ester-based solvent is preferable, an aliphatic alcohol-based solvent having 1 to 18 carbon atoms, a glycol monoether-based solvent having 3 to 19 carbon atoms, or an ester-based solvent having 4 to 12 carbon atoms is more preferable, and IPA, propylene glycol monomethyl ether, ethyl lactate, γ-butyrolactone, propylene carbonate, or PGMEA is still more preferable.

Among these, the monocarboxylic acid ester-based solvent, the lactone-based solvent, or the carbonate-based solvent is preferable as the ester-based solvent.

Two or more kinds of the solvents may be used in combination. In addition, three or more kinds of the solvents may be used. That is, the chemical liquid may include three or more kinds of solvents.

In a case where two or more kinds of the solvents are used in combination, it is preferable to use one or more organic solvents selected from the group consisting of an alcohol-based solvent, a glycol ether-based solvent, and an ester-based solvent, and water in combination, and it is more preferable to use one or two kinds of the organic solvents and water in combination.

The preferred aspects of the organic solvent are as described above, but among those, IPA, propylene glycol monomethyl ether, ethyl lactate, γ-butyrolactone, propylene carbonate, or PGMEA is preferable as the organic solvent.

In a case where the chemical liquid includes water, the content of water is preferably 80% by mass or less, more preferably less than 80% by mass, still more preferably 50% by mass or less, and particularly preferably 30% by mass or less with respect to a total mass of the solvent included in the chemical liquid. The lower limit is not particularly limited, and may be, for example, 0% by mass.

In addition, in a case where the content of the organic solvent is defined as A, the content of the water is defined as B, and A+B is defined as 100, a content ratio A/B of the organic solvent to water is preferably 20/80 to 100/0, more preferably 30/70 to 90/10, and still more preferably 40/60 to 80/20.

The content of the solvent in the chemical liquid is preferably 90% to 99.999% by mass, more preferably 95% to 99.9% by mass, and still more preferably 97% to 99.9% by mass with respect to the total mass of the chemical liquid.

In a case where two or more kinds of the solvents are used in combination, a total content thereof is preferably within the range.

### (Polymerization Inhibitor)

From the viewpoint of improving the stability of the chemical liquid, the chemical liquid 1 preferably includes a polymerization inhibitor.

The polymerization inhibitor is not particularly limited, and a known polymerization inhibitor may be selected according to the kind of the crosslinkable group contained in the specific compound 1, but a radical polymerization inhibitor is preferable.

The polymerization inhibitor preferably includes at least one compound selected from the group consisting of a phenol-based compound, a quinone-based compound, a free radical-based compound, an amine-based compound, and a phosphine-based compound, and from the viewpoint of polymerization inhibition ability, the free radical-based compound is more preferable.

Examples of the phenol-based compound include 4-methoxyphenol, hydroquinone, 2-tert-butylhydroquinone, 4-tert-butylcatechol, pentaerythritol tetrakis [3-(3,5-di-tert-butyl-4-hydroxyphenyl) propionate], 2,5-di-tert-butyl-4-methylphenol, 2,6-di-tert-butyl-4-methylphenol, 4,4′-thiobis(3-methyl-6-t-butylphenol), 2,2′-methylenebis(4-methyl-6-t-butylphenol), 4-methoxynaphthol, 2,4-bis(octylthiomethyl)-6-methylphenol, p-nitrosophenol, and α-nitroso-β-naphthol.

Examples of the quinone-based compound include 1,4-benzoquinone, 1,2-benzoquinone, and 1,4-naphthoquinone.

Examples of the free radical-based compound include poly(4-methacryloyloxy-2,2,6,6-tetramethylpiperidine-N-oxyl), 4-hydroxy-2,2,6,6-tetramethylpiperidine 1-oxyl, 2,2,6,6-tetramethylpiperidine 1-oxyl, 2,2-diphenyl-1-picrylhydrazyl, and triphenylverdazyl.

Examples of the amine-based compound include p-phenylenediamine, 4-aminodiphenylamine, N,N-diethylhydroxylamine, N,N′-diphenyl-p-phenylenediamine, N-isopropyl-N′-phenyl-p-phenylenediamine, N-(1,3-dimethylbutyl)-N′-phenyl-p-phenylenediamine, N,N′-di-2-naphthyl-p-phenylenediamine, diphenylamine, N-phenyl-β-naphthylamine, 4,4′-dicumyl-diphenylamine, 4,4′-dioctyl-diphenylamine, phenothiazine, 2-methoxyphenothiazine, phenoxazine, N-nitrosodiphenylamine, N-nitrosophenylnaphthylamine, N-nitrosodinaphthylamine, p-nitrosodiphenylamine, N-nitroso-N-phenylhydroxylamine, N-nitroso-N-phenylhydroxylamine aluminum, and cupferron. Each of the compounds exemplified as the amine-based compound may form a metal salt or a metal complex.

Examples of the phosphine-based compound include (2,4-di-tert-butylphenyl) phosphite.

In addition, as the polymerization inhibitor, nitrobenzene-based compounds such as nitrobenzene and 4-nitrotoluene, and thiol ethers such as dioctadecyl 3,3′-thiodipropionate, dilauryl thiodipropionate, dimyristyl thiodipropionate, and distearyl thiodipropionate may also be included.

The molecular weight of the polymerization inhibitor is preferably 1,000 or less, more preferably 800 or less, and still more preferably 500 or less. The lower limit of the molecular weight is not particularly limited, but is preferably 80 or more.

The content of the polymerization inhibitor is preferably 0.0001 parts by mass or more, more preferably 0.001 parts by mass or more, still more preferably 0.005 parts by mass or more, and particularly preferably 0.010 parts by mass or more with respect to 100 parts by mass of the content of the specific compound 1.

In addition, the content of the polymerization inhibitor is preferably 10.0 parts by mass or less, more preferably 1.000 part by mass or less, and still more preferably 0.100 parts by mass or less with respect to 100 parts by mass of the content of the specific compound 1.

The chemical liquid 1 may include one kind of polymerization inhibitor alone, or may include two or more kinds of the polymerization inhibitors. In a case where the composition includes two or more kinds of the polymerization inhibitors, a total amount thereof is preferably within the range.

### <Method for Producing Chemical Liquid 1>

A method for producing the chemical liquid 1 is not particularly limited, and the chemical liquid 1 can be produced, for example, by mixing the respective components.

The order or timing of mixing the respective components in the chemical liquid is not particularly limited. Examples of the method include a method for producing a chemical liquid by adding the specific compound 1 to a stirrer such as a mixing mixer into which a purified solvent has been incorporated, and then sufficiently stirring the mixture.

In a case where the chemical liquid includes other components in addition to the specific compound 1, the other components may be added at the same time as the specific compound 1 or may be added at different timings.

In the production step of producing the chemical liquid 1, the steps described below may be performed.

### (Metal Removing Step)

In the production method, a metal removal step of removing a metal component from the components and/or chemical liquid (hereinafter also referred to as a “substance to be purified”) may be performed.

### (Filtration Step)

It is preferable that the production method include a filtration step of filtering a liquid such that foreign substances, coarse particles, and the like are removed from the liquid.

The filtration method is not particularly limited, and a publicly known filtration method can be used. Among these, filtering using a filter is preferable.

### (Static Neutralization Step)

The method for producing the chemical liquid may further include a static neutralization step of statically neutralizing the chemical liquid.

### <Substrate>

The substrate used in the first embodiment of the method for producing a modified substrate of the embodiment of the present invention is a substrate (hereinafter also simply referred to as a “substrate”) having at least two surfaces of a first surface and a second surface, which are composed of materials different from each other.

The material constituting the first surface and the material constituting the second surface are not particularly limited as long as they are different from each other, and may be any of an organic material or an inorganic material. However, from the viewpoint that the effect of the present invention is more excellent, it is preferable that at least one of the first surface or the second surface includes a metal atom, and it is more preferable that the first surface includes a metal atom.

Furthermore, in the present specification, metalloid atoms such as boron, silicon, germanium, arsenic, antimony, and tellurium are also included in the metal atoms.

In a case where the first surface or the second surface includes a metal atom, the metal atom may be included, for example, as a metal (for example, a simple metal) or a metal atom included in a compound. In addition, the metal atom may be included as a metal atom that is included in a pure metal or an alloy.

As the metal atom, a transition metal atom is preferable, at least one metal atom selected from the group consisting of a copper atom, a cobalt atom, a titanium atom, a tantalum atom, a tungsten atom, a ruthenium atom, and a molybdenum atom is preferable, at least one metal atom selected from the group consisting of the titanium atom, the tungsten atom, the ruthenium atom, and the molybdenum atom is more preferable, and the ruthenium atom or the tungsten atom is still more preferable.

In a case where the first surface includes at least one metal atom selected from the group consisting of the copper atom, the cobalt atom, the titanium atom, the tantalum atom, the tungsten atom, the ruthenium atom, and the molybdenum atom, from the viewpoint that the effect of the present invention is more excellent, it is preferable that the specific compound 1 has, as the functional group bonded to or adsorbed on the first surface, a group selected from the group consisting of a nitrogen-containing group, a phosphonic acid ester, a phosphoric acid group (—PO₄H₂) or a salt thereof, a phosphonic acid group (—PO₃H₂) or a salt thereof, a sulfo group (—SO₃H) or a salt thereof, a carboxy group (—COOH) or a salt thereof, a hydroxy group (—OH), and a thiol group (—SH).

In addition, examples of other preferred aspects of the first surface and the second surface include an aspect in which one of the first surface and the second surface is a metal surface composed of a metal and the other is a non-metal surface composed of a non-metal (hereinafter also referred to as an aspect A).

Examples of the metal include a pure metal or an alloy.

Examples of the non-metal include a metal carbide, a metal oxide, a metal nitride, a metal oxynitride, and an organic material.

It is preferable that the pure metal and the alloy are composed of the preferred metal atoms exemplified above.

In addition, the metal carbide, the metal oxide, the metal nitride, and the metal oxynitride are preferably the metal carbide, the metal oxide, the metal nitride, and the metal oxynitride, which are exemplified as the preferred metal atoms as described above.

In the aspect A, it is preferable that the first surface is a metal surface and the second surface is a non-metal surface.

In a case where the first surface is a metal surface and the second surface is a non-metal surface, from the viewpoint that the effect of the present invention is more excellent, it is preferable that the specific compound 1 has, as the functional group bonded to or adsorbed on the first surface, a group selected from the group consisting of a nitrogen-containing group, a phosphonic acid ester, a phosphoric acid group (—PO₄H₂), a phosphonic acid group or a salt thereof, a sulfo group (—SO₃H) or a salt thereof, a carboxy group (—COOH) or a salt thereof, a hydroxy group (—OH), and a thiol group (—SH).

In addition, examples of a preferred aspect of the first surface and the second surface include an aspect in which the first surface is a surface composed of a material selected from the group consisting of a metal (a pure metal or an alloy), a metal carbide, a metal oxide, a metal nitride, and a metal oxynitride, and the second surface is a surface composed of a material different from that of the first surface and selected from the group consisting of a metal (a pure metal or an alloy), a metal carbide, a metal oxide, a metal nitride, and a metal oxynitride (hereinafter also referred to as an aspect B). The expression that the first surface and the second surface are composed of different kinds of materials is intended to mean that two kinds of materials are selected as the first surface and the second surface from five kinds of materials of a metal, a metal carbide, a metal oxide, a metal nitride, and a metal oxynitride.

More specific examples of the aspect B include an aspect in which the first surface is a metal surface composed of a metal and the second surface is a metal oxide surface composed of a metal oxide (hereinafter also referred to as an aspect B1), an aspect in which the first surface is a metal nitride surface composed of a metal nitride and the second surface is a metal oxide surface composed of a metal oxide (hereinafter also referred to as an aspect B2), and an aspect in which the first surface is a metal oxide surface composed of a metal oxide and the second surface is a metal surface composed of a metal (hereinafter also referred to as an aspect B3).

In a case of the aspect B1, examples of the metal include copper, cobalt, titanium, tantalum, tungsten, ruthenium, and molybdenum.

Examples of the metal oxide include silicon oxide, silicon oxycarbide (SiOC), and tetraethyl orthosilicate (TEOS).

In a case of the aspect B2, examples of the metal nitride include titanium nitride.

Examples of the metal oxide include silicon oxide, silicon oxycarbide (SiOC), and tetraethyl orthosilicate (TEOS).

In addition, in a case of the aspect B1 or the aspect B2, from the viewpoint that the effect of the present invention is more excellent, it is preferable that the specific compound 1 has, as the functional group bonded to or adsorbed on the first surface, a group selected from the group consisting of a nitrogen-containing group, a phosphonic acid group (—PO₃H₂) or a salt thereof, a phosphonic acid ester, a phosphoric acid group (—PO₄H₂) or a salt thereof, a sulfo group (—SO₃H) or a salt thereof, a carboxy group (—COOH), a hydroxy group (—OH), and a thiol group (—SH).

In particular, in a case where the functional group bonded to or adsorbed on the first surface is the nitrogen-containing group, the functional group is easily bonded to or adsorbed on a tungsten surface, a ruthenium surface, or a molybdenum surface, and therefore, the ALD coating film is more easily inhibited. In addition, in a case where the functional group bonded to or adsorbed on the first surface is the phosphonic acid group (—PO₃H₂) or a salt thereof, or the phosphonic acid ester, the functional group is easily bonded to or adsorbed on the copper surface or the cobalt surface, and therefore, the ALD coating film is more easily inhibited.

In a case of the aspect B3, examples of the metal oxide include silicon oxide, silicon oxycarbide (SiOC), and tetraethyl orthosilicate (TEOS).

Examples of the metal include silicon.

In a case of the aspect B3, from the viewpoint that the effect of the present invention is more excellent, it is preferable that the specific compound 1 has the hydrolyzable silyl group as the functional group bonded to or adsorbed on the first surface.

### [Step 1]

The method for producing a modified substrate of the embodiment of the present invention (first embodiment) includes a step 1.

As described above, the step 1 is a step of bringing a substrate (hereinafter also simply referred to as a “substrate”) having at least two surfaces of a first surface and a second surface, which are composed of materials different from each other, into contact with a chemical liquid (chemical liquid 1) including a compound (specific compound 1) which has a functional group that bonds to or adsorbs to the first surface and the crosslinkable group and has a molecular weight of 500 or less, and a solvent, to form a first coating film on the first surface.

A method for bringing the substrate into contact with the chemical liquid 1 is not particularly limited, and examples thereof include a method of applying or spraying the chemical liquid 1 onto the substrate and a method of immersing the substrate in the chemical liquid 1. The method of applying the chemical liquid 1 onto the substrate is not particularly limited, a known method can be used, and examples thereof include a spin coating method. In addition, in a case where the substrate is immersed in the chemical liquid 1, the chemical liquid 1 may be subjected to convection.

A temperature of the chemical liquid 1 in a case where the substrate is brought into contact with the chemical liquid 1 is not particularly limited, but is preferably 0° C. to 50° C., and more preferably 10° C. to 30° C.

It is also preferable that the substrate and the chemical liquid 1 are brought into contact with each other, and the substrate on which the first coating film is formed on the first surface is subjected to a rinsing treatment. The specific compound 1 adhering to a region other than a desired region on the substrate can be removed from the substrate by the rinsing treatment.

The rinsing method is not particularly limited, and examples thereof include a method of bringing a rinsing liquid into contact with the substrate. Examples of the contact method include the same method as the method of bringing the chemical liquid 1 into contact with the substrate. The temperature of the rinsing liquid during the contact is not particularly limited, but is preferably 0° C. to 50° C., and more preferably 10° C. to 30° C.

The rinsing liquid is not particularly limited, and examples thereof include the solvent included in the chemical liquid 1. A solvent of the same type as the solvent included in the chemical liquid 1 may be used as the rinsing liquid.

### [Step 2]

The method for producing a modified substrate of the embodiment of the present invention (first embodiment) includes a step 2.

As described above, the step 2 is a step of subjecting the substrate obtained in the step 1 (the substrate having the first coating film) to an atomic layer deposition treatment (ALD treatment) to form a second coating film on the second surface.

In a case where the substrate obtained in the step 1 is subjected to the ALD treatment, the formation of the second coating film is inhibited by the first coating film, and therefore, a modified substrate in which the second coating film is formed with good selectivity on a region (second surface) where the first coating film is not formed can be obtained.

Since the material used for forming a Langmuir-Blodgett film or a self-assembled monolayer film (SAM film) is often a low-molecular-weight material, the material is very effective for selectively forming a modified film on a fine region on a substrate, as compared with a high-molecular-weight material, but the material is often inferior in resistance in a case where the substrate is heated in the ALD treatment.

In contrast, in the step 2 of the present invention, since the specific compound 1 is a low-molecular-weight material but has a crosslinkable group, in a case where the substrate is heated in the ALD step, the first coating film is cured to form a cured film and sufficient heat resistance can be exhibited, making it possible to inhibit the formation of an ALD coating film in a fine region while maintaining the heat resistance.

In the ALD treatment, a precursor serving as a raw material of the second coating film is supplied to a surface of the substrate obtained in the step 1. It is general to use two or more kinds of the precursors.

The material constituting the second coating film can be controlled by the kind of a precursor to be supplied, the supply atmosphere, an oxidant, and the like. The second coating film formed by the ALD treatment is not particularly limited, but is preferably a metal film, a metal oxide film, or a metal nitride film, and more preferably the metal film or the metal oxide film.

Examples of the metal constituting the metal film include aluminum, titanium, chromium, iron, cobalt, nickel, copper, zinc, yttrium, zirconium, niobium, molybdenum, ruthenium, palladium, lanthanum, cerium, hafnium, tantalum, tungsten, platinum, and bismuth.

Examples of the metal oxide constituting the metal oxide film include aluminum oxide, titanium oxide, zinc oxide, zirconium oxide, hafnium oxide, and tantalum oxide.

Examples of the metal nitride constituting the metal nitride film include titanium nitride and tantalum nitride.

In addition, in the ALD treatment, a treatment for altering a surface of the region where the first coating film is not formed may be performed.

The ALD treatment is not particularly limited, but a thermal ALD method is preferable. Furthermore, a step 4 may be separately provided as a heating step of reacting the crosslinkable groups with each other, which will be described later.

From the viewpoint that the reaction between the crosslinkable groups can be efficiently performed, the substrate heating temperature in the ALD treatment is preferably 100° C. to 400° C., more preferably 150° C. to 400° C., and still more preferably 200° C. to 300° C.

In the step 2, a difference between the thickness of the second coating film on the second surface and the thickness of the second coating film on the region where the first coating film is formed (the thickness of the second coating film on the second surface—the thickness of the second coating film on the region where the first coating film is formed) is preferably 1.0 nm or more, more preferably 1.2 nm or more, and still more preferably 1.5 nm or more.

The upper limit of the difference in thickness is not particularly limited, but may be, for example, 100 nm or less.

### [Method for Producing Modified Substrate (Second Embodiment)]

As described above, a second embodiment of the method for producing a modified substrate of the embodiment of the present invention is a method for producing a modified substrate, the method including a step 1 of bringing a substrate having at least two surfaces of a first surface and a second surface, which are composed of materials different from each other, into contact with a chemical liquid (hereinafter also referred to as a “chemical liquid 2”) including a compound (hereinafter also referred to as a “specific compound 2”) which has a group selected from the group consisting of a nitrogen-containing group, a phosphonic acid group (—PO₃H₂) or a salt thereof, a phosphonic acid ester, a phosphoric acid group or a salt thereof, a carboxy group or a salt thereof, a hydroxy group, a thiol group, and a hydrolyzable silyl group, and a crosslinkable group, and has a molecular weight of 500 or less, and a solvent, to form a first coating film on the first surface; and a step 2 of subjecting the substrate obtained in the step 1 to an atomic layer deposition treatment to form a second coating film on the second surface.

Hereinafter, the chemical liquid 2 used in the step 1 will be described in detail.

### <Chemical Liquid 2>

The chemical liquid 2 includes the specific compound 2 and a solvent.

### (Specific Compound 2)

As described above, the specific compound 2 is a compound which has a group (specific group) selected from the group consisting of a nitrogen-containing group, a phosphonic acid group (—PO₃H₂) or a salt thereof, a phosphonic acid ester, a phosphoric acid group or a salt thereof, a carboxy group or a salt thereof, a hydroxy group, a thiol group, and a hydrolyzable silyl group, and a crosslinkable group, and has a molecular weight of 500 or less.

As described later, since the first surface of the substrate preferably includes a metal atom, the specific compound 2 has the specific group, whereby a strong bond is formed between the first surface including a metal atom and the specific group, making it possible to obtain a stable first coating film.

Specific aspects and suitable aspects of the specific group are the same as the specific aspects and the suitable aspects of the functional group bonded to or adsorbed on the first surface in the first embodiment, respectively.

Among these, the specific group is preferably a group selected from the group consisting of the nitrogen-containing group, the phosphonic acid group (—PO₃H₂) or a salt thereof, the phosphonic acid ester, the phosphoric acid group or a salt thereof, the carboxy group or a salt thereof, the hydroxy group, the thiol group, and the hydrolyzable silyl group, more preferably a group selected from the group consisting of the nitrogen-containing group, the phosphonic acid group (—PO₃H₂) or a salt thereof, the phosphonic acid ester, the carboxy group or a salt thereof, the hydroxy group, the thiol group, and the hydrolyzable silyl group, and still more preferably a group selected from the group consisting of the nitrogen-containing group, the phosphonic acid group (—PO₃H₂) or a salt thereof, and the phosphonic acid ester.

The specific compound 2 has a crosslinkable group. Specific aspects and suitable aspects of the crosslinkable group in the specific compound 2 are the same as the specific aspects and the suitable aspects of the crosslinkable group in the specific compound 1, respectively.

The number of the crosslinkable groups contained in the specific compound 2 is not particularly limited as long as it is 1 or more, but the number of the crosslinkable groups is preferably 1 to 3, and more preferably 1.

The specific compound 2 preferably has a structure exhibiting alignment properties. Specific aspects and suitable aspects of the structure exhibiting alignment in the specific compound 2 are the same as the specific aspects and the suitable aspects of the structure exhibiting alignment in the specific compound 1, respectively.

Among these, the specific compound 2 is preferably the above-described compound represented by Formula (S1).

The molecular weight of the specific compound 2 is not particularly limited as long as it is 500 or less, but the molecular weight is preferably 50 to 450, more preferably 100 to 450, and still more preferably 150 to 400.

The content of the specific compound 2 is preferably 0.0001% to 10.0% by mass, more preferably 0.001% to 1.0% by mass, and still more preferably 0.01% to 0.5% by mass with respect to a total mass of the chemical liquid 2.

Two or more kinds of the specific compounds 2 may be used in combination.

In a case where two or more kinds of the specific compounds 2 are used in combination, a total content thereof is preferably within the range.

### (Solvent)

The chemical liquid 2 includes a solvent. Specific aspects and suitable aspects of the solvent are the same as the specific aspects and the suitable aspects of the solvent included in the chemical liquid 1, respectively.

The content of the solvent in the chemical liquid is preferably 90% to 99.999% by mass, more preferably 95% to 99.9% by mass, and still more preferably 97% to 99.9% by mass with respect to the total mass of the chemical liquid.

Two or more kinds of the solvents may be used in combination.

In a case where two or more kinds of the solvents are used in combination, a total content thereof is preferably within the range.

### (Polymerization Inhibitor)

From the viewpoint of improving the stability of the chemical liquid, the chemical liquid 2 preferably includes a polymerization inhibitor. Specific aspects and suitable aspects of the polymerization inhibitor are the same as the specific aspects and the suitable aspects of the polymerization inhibitor included in the chemical liquid 1, respectively.

The content of the polymerization inhibitor is preferably 0.0001 parts by mass or more, more preferably 0.001 parts by mass or more, still more preferably 0.005 parts by mass or more, and particularly preferably 0.010 parts by mass or more with respect to 100 parts by mass of the content of the specific compound 2.

In addition, the content of the polymerization inhibitor is preferably 10.0 parts by mass or less, more preferably 1.000 part by mass or less, and still more preferably 0.100 parts by mass or less with respect to 100 parts by mass of the content of the specific compound 2.

The chemical liquid 2 may include one kind of polymerization inhibitor alone, or may include two or more kinds of the polymerization inhibitors. In a case where the composition includes two or more kinds of the polymerization inhibitors, a total amount thereof is preferably within the range.

### <Method for Producing Chemical Liquid>

A method for producing the chemical liquid 2 is not particularly limited, and specific aspects and suitable aspects thereof are each the same as those of the method for producing the chemical liquid 1.

### <Substrate>

The substrate used in the second embodiment of the method for producing a modified substrate of the embodiment of the present invention is a substrate (hereinafter also simply referred to as a “substrate”) having at least two surfaces of a first surface and a second surface, which are composed of materials different from each other. Specific aspects and suitable aspects of the substrate are the same as the specific aspects and the suitable aspects of the substrate used in the first embodiment, respectively.

### [Step 1]

The method for producing a modified substrate of the embodiment of the present invention (second embodiment) includes a step 1.

As described above, the step 1 is a step of bringing a substrate having at least two surfaces of a first surface and a second surface, which are composed of materials different from each other, into contact with a chemical liquid (chemical liquid 2) including a compound (specific compound 2) which has a group selected from the group consisting of a nitrogen-containing group, a phosphonic acid group (—PO₃H₂) or a salt thereof, a phosphonic acid ester, a phosphoric acid group or a salt thereof, a carboxy group or a salt thereof, a hydroxy group, a thiol group, and a hydrolyzable silyl group, and a crosslinkable group, and has a molecular weight of 500 or less, and a solvent, to form a first coating film on the first surface.

The method of bringing the substrate into contact with the chemical liquid 2 is not particularly limited, and specific aspects and suitable aspects thereof are each the same as those of the method of bringing the substrate into contact with the chemical liquid 1.

In addition, it is also preferable that the substrate and the chemical liquid 2 are brought into contact with each other, and the substrate on which the first coating film is formed on the first surface is subjected to a rinsing treatment. Specific aspects and suitable aspects of the rinsing method are the same as the specific aspects and the suitable aspects of the rinsing method in the step 1 of the first embodiment, respectively.

### [Step 2]

The method for producing a modified substrate of the embodiment of the present invention (second embodiment) includes a step 2.

As described above, the step 2 is a step of subjecting the substrate obtained in the step 1 (the substrate having the first coating film) to an atomic layer deposition treatment (ALD treatment) to form a second coating film on the second surface. Specific aspects and suitable aspects of the step 2 in the second embodiment of the method for producing a modified substrate of the embodiment of the present invention are the same as the specific aspects and the suitable aspects of the step 2 in the first embodiment described above, respectively.

### [Other Steps]

### [Step 3]

The method for producing a modified substrate of the embodiments of the present invention (the first embodiment and the second embodiment) may include a step 3 of removing the first coating film formed on the substrate in the step 1 after the step 2. By carrying out the step 3 after the step 2, a modified substrate in which the second coating film is formed only on the second surface can be obtained.

A method for removing the first coating film is not particularly limited, and examples thereof include dry etching, wet etching, and a combination thereof.

Examples of the dry etching include a method of supplying reactive ions or reactive radicals to the surface of the modified substrate having the first coating film. The reactive ions or the reactive radicals may be generated by plasma or the like, and are preferably generated using a mixed gas including one or more gases selected from the group consisting of oxygen, nitrogen, and hydrogen. The mixed gas may include a rare gas. In addition, the dry etching may be physical etching using a sputtering phenomenon.

In the wet etching, an etchant may be supplied to a surface of the modified substrate having the first coating film. Examples of the etchant include an etchant including an oxidant such as ozone and an etchant including an organic solvent. Examples of the organic solvent in the etchant including an organic solvent include the organic solvent contained in the chemical liquid, and the hydrocarbon-based solvent is preferable.

### [Step 4]

The method for producing a modified substrate of the embodiment of the present invention (first embodiment and second embodiment) may include a step 4 of heating the modified substrate. It is preferable that the step 4 is carried out before the step 2.

The heating temperature is not particularly limited, but is preferably 100° C. to 400° C., more preferably 150° C. to 400° C., and still more preferably 200° C. to 300° C.

The heating method is not particularly limited, and examples thereof include a method of contacting with a heating element (for example, heating with a hot plate) and a method of irradiation with infrared rays.

### [Method for Producing Semiconductor Device]

The present invention also relates to a method for producing a semiconductor device, the method including the method for producing a modified substrate.

The method for producing a modified substrate of the embodiment of the present invention can be used in any of steps for producing a semiconductor device, and can be used, for example, in a step of treating a semiconductor substrate in the method for producing a semiconductor device.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### [Method for Preparing Chemical Liquid]

The chemical liquids used in Examples and Comparative Examples were prepared by mixing components at the proportions shown in the table which will be given later.

Furthermore, the preparation, filling, storage, and the like of the chemical liquid were all performed in a clean room that satisfies a level equal to or lower than ISO Class 2. In addition, the container used for the preparation, filling, storage, and the like of the chemical liquid was used after being cleaned with a solvent used for the preparation or the prepared chemical liquid.

### [Evaluation A]

According to the following procedure, a substrate in which a first coating film was formed on a substrate consisting of only a first surface was prepared using a chemical liquid which will be described later, and the ALD inhibitory properties were evaluated.

### [Manufacture of Sample Substrate for Evaluation (Method for Forming First Coating Film)]

First, as a substrate, a W layer wafer having a tungsten layer formed by a CVD method, an Ru layer wafer having a ruthenium layer formed by a CVD method, a TiN layer wafer having a titanium nitride layer formed by a CVD method, and a TEOS layer wafer having a tetraethyl orthosilicate (Si(OC₂H₅)₄) layer formed by a plasma CVD method, each of these layers being formed on one surface of a commercially available silicon wafer (diameter: 12 inches), were prepared. The film forming conditions were adjusted so that the thicknesses of the W layer, the Ru layer, the TiN layer, and the TEOS layer were each 20 nm.

The silicon wafer, and the W layer wafer, Ru layer wafer, TiN layer wafer, and TEOS layer wafer obtained by film formation as described above were each cut into a 2 cm square, subjected to a rinsing treatment with isopropyl alcohol (IPA), and then dried by blowing nitrogen gas to each wafer.

The rinsing treatment was carried out by immersing the substrate in IPA, in which the immersion was performed while stirring IPA placed in a container with a magnetic stirrer under the condition of 250 rpm. The temperature of IPA was 25° C. and the immersion time was 30 seconds.

Each wafer after the rinsing treatment was immersed in each chemical liquid. Each wafer was immersed in the chemical liquid while stirring the chemical liquid placed in a container under the condition of 250 rpm using a magnetic stirrer. The temperature of the chemical liquid was 25° C. and the immersion time was 10 minutes.

Each wafer after the immersion treatment was subjected to a rinsing treatment with IPA by the same procedure as described above, and then dried with nitrogen gas to obtain a sample (sample for evaluation) in which a first coating film was formed on each wafer.

### [ALD Inhibitory Properties]

Using an atomic layer deposition device (AD-230LP, manufactured by SAMCO Inc.), an aluminum oxide layer (ALD coating film) was formed on the sample (sample for evaluation) obtained in [Manufacture of Sample Substrate for Evaluation (Method for Forming First Coating Film)] and a sample in a case where the first coating film was not formed (untreated sample). Trimethyl aluminum was used as an organic metal raw material and water was used as an oxidant.

Furthermore, the ALD treatment temperature was set to 200° C., and each sample was subjected to the ALD treatment under the condition that the film thickness was 5 nm with respect to each sample (untreated sample) in a case where the first coating film was not formed.

The film thickness of the ALD coating film in the sample after the ALD treatment was measured using an X-ray fluorescence analysis (XRF) device (AZX400 manufactured by Rigaku Corporation). The film thickness of the ALD coating film was measured at five points of the sample and an average value thereof was taken as the film thickness.

The value obtained according to the following Expression (A) was evaluated for an ALD inhibition amount (nm) according to the following standard. The larger the ALD inhibition amount (nm), the more difficult it is for the coating film to be deposited by the ALD treatment.

ALD inhibition amount (nm)=(Film thickness (5 nm) of ALD coating film of untreated sample)−(Film thickness (nm) of ALD coating film of sample for evaluation) Expression (A):

### (Evaluation Standard)

A: The ALD inhibition amount is 2.0 nm or more.
B: The ALD inhibition amount is 1.0 nm or more and less than 2.0 nm.
C: The ALD inhibition amount is less than 1.0 nm.

### [Results]

Table 1 which will be described later shows each component used for the preparation of a chemical liquid and a content ratio (mass ratio) thereof.

In Table 1, the column of “Molecular weight” shows the molecular weight of a specific compound. Furthermore, for the compound C-1, the molecular weight represents the weight-average molecular weight.

In addition, the evaluation results of the ALD inhibitory properties are shown in Tables 2 to 5 which will be described later.

Furthermore, the results assuming that a W layer was used as the first surface and a TEOS layer was used as the second surface are shown in Table 2.

The results assuming that an Ru layer was used as the first surface and a TEOS layer was used as the second surface are shown in Table 3.

The results assuming that a TiN layer was used as the first surface and a TEOS layer was used as the second surface are shown in Table 4.

The results assuming that a TEOS layer was used as the first surface and an Si layer was used as the second surface are shown in Table 5.

In Tables 2 to 5, the column of “Film formation amount” shows the film thickness of the ALD coating film formed using each sample for evaluation. In addition, the column of “ALD Inhibition amount” shows the ALD inhibition amount obtained according to Expression (A).

In Table 1, the structures or names of the respective components used for the preparation of the chemical liquid are shown below.

### <Specific Compound>

The structures of the specific compounds (A-1 to A-10) are shown below.

Furthermore, the specific compound is a compound corresponding to the specific compound 1 or the specific compound 2.

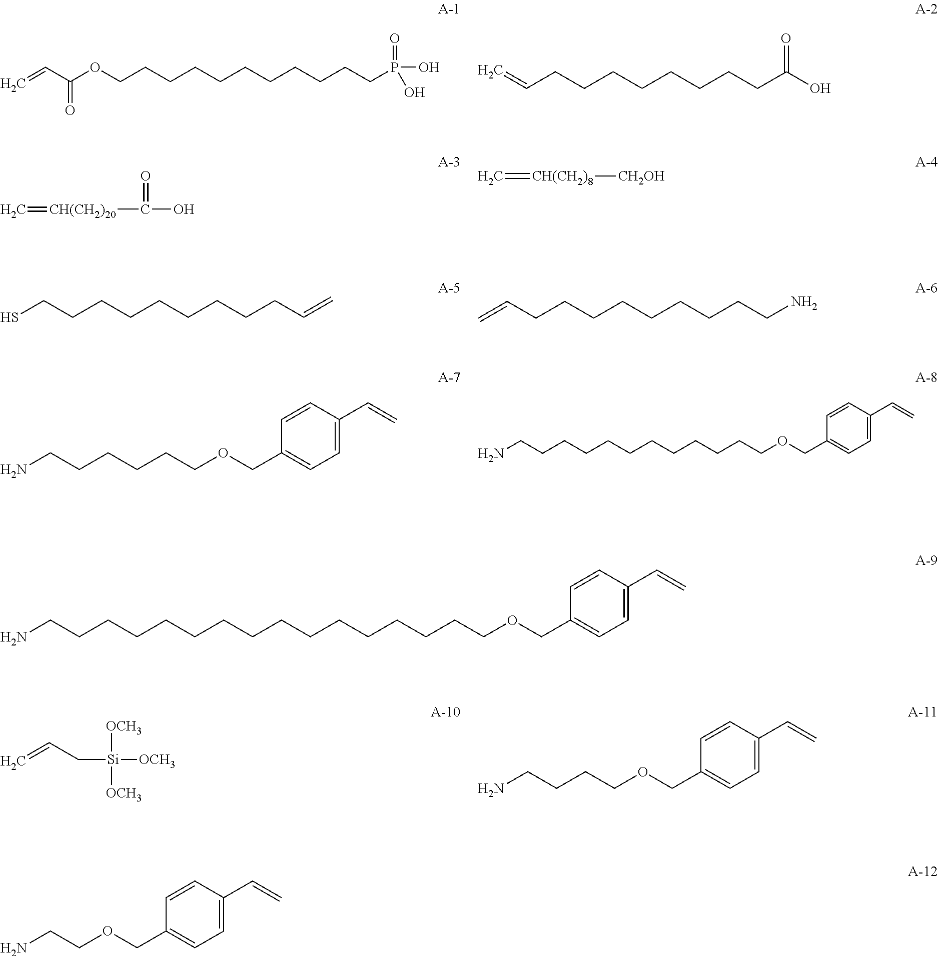

### <Other Compounds>

B-1: The following compound

CH₃(CH₂)₁₆CH₂NH₂
C-1: A polymer having the following structure described in paragraphs and of WO2019/167704A

A polymer having the following structure was synthesized according to the method described in paragraph of WO2019/167704A. The synthesized polymer having the following structure had a weight-average molecular weight of 5,200 and a number-average molecular weight of 4,900.

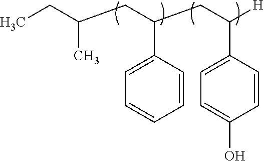

### <Solvent>

S-1: Propylene glycol monomethyl ether
S-2: Methyl isobutyl carbinol

TABLE 1

| | | Molecular | Chemical liquid | | | | | | | | | |
|---|---|---|---|---|---|---|---|---|---|---|---|---|
| | | weight | X-1 | X-2 | X-3 | X-4 | X-5 | X-6 | X-7 | X-8 | X-9 | X-10 |
| Specific | A-1 | 306.3 | 0.1 | | | | | | | | | |
| compound | A-2 | 184.3 | | 0.1 | | | | | | | | |
| | A-3 | 352.6 | | | 0.1 | | | | | | | |
| | A-4 | 170.3 | | | | 0.1 | | | | | | |
| | A-5 | 186.4 | | | | | 0.1 | | | | | |
| | A-6 | 169.3 | | | | | | 0.1 | | | | |
| | A-7 | 233.4 | | | | | | | 0.1 | | | |
| | A-8 | 317.5 | | | | | | | | 0.1 | | |
| | A-9 | 373.6 | | | | | | | | | 0.1 | |
| | A-10 | 162.3 | | | | | | | | | | 0.1 |
| | A-11 | 205.3 | | | | | | | | | | |
| | A-12 | 177.1 | | | | | | | | | | |
| | B-1 | 269.5 | | | | | | | | | | |
| | C-1 | 5200 | | | | | | | | | | |

| | | | | | | | | | | | |
|---|---|---|---|---|---|---|---|---|---|---|---|
| Solvent | S-1 | 99.9 | 99.9 | 99.9 | 99.9 | 99.9 | 99.9 | 99.9 | 99.9 | 99.9 | 99.9 |
| | S-2 | | | | | | | | | | |

| | | | | | | | | | | |
|---|---|---|---|---|---|---|---|---|---|---|
| total (wt %) | 100 | 100 | 100 | 100 | 100 | 100 | 100 | 100 | 100 | 100 |

| | | Molecular | Chemical liquid | | | | | | | | |
|---|---|---|---|---|---|---|---|---|---|---|---|
| | | weight | X-11 | X-12 | X-13 | X-14 | X-15 | X-16 | X-17 | R-1 | R-2 |
| Specific | A-1 | 306.3 | | | | | | | | | |
| compound | A-2 | 184.3 | | | | | | | | | |
| | A-3 | 352.6 | | | | | | | | | |
| | A-4 | 170.3 | | | | | | | | | |
| | A-5 | 186.4 | | | | | | | | | |
| | A-6 | 169.3 | 0.001 | 0.5 | 0.1 | 0.1 | | | | | |
| | A-7 | 233.4 | | | | | | | | | |
| | A-8 | 317.5 | | | | | 0.05 | | | | |
| | A-9 | 373.6 | | | | | 0.05 | | | | |
| | A-10 | 162.3 | | | | | | | | | |
| | A-11 | 205.3 | | | | | | 0.1 | | | |
| | A-12 | 177.1 | | | | | | | 0.1 | | |
| | B-1 | 269.5 | | | | | | | | 0.1 | |
| | C-1 | 5200 | | | | | | | | | 0.1 |

| | | | | | | | | | | |
|---|---|---|---|---|---|---|---|---|---|---|
| Solvent | S-1 | 99.999 | 99.5 | | 49.95 | 99.9 | 99.9 | 99.9 | 99.9 | 99.9 |
| | S-2 | | | 99.9 | 49.95 | | | | | |

| | | | | | | | | | |
|---|---|---|---|---|---|---|---|---|---|
| total (wt %) | 100 | 100 | 100 | 100 | 100 | 100 | 100 | 100 | 100 |

TABLE 2

| | | W layer | | | TEOS layer | | |
|---|---|---|---|---|---|---|---|
| | | Film | ALD | | Film | ALD | |
| | | formation | Inhibition | | formation | Inhibition | |
| | Chemical | amount | amount | | amount | amount | |
| | liquid | (nm) | (nm) | Evaluation | (nm) | (nm) | Evaluation |
| Example 1A | X-1 | 3.5 | 1.5 | B | 5 | 0 | C |
| Example 2A | X-2 | 2.6 | 2.4 | A | 5 | 0 | C |
| Example 3A | X-3 | 3 | 2 | A | 5 | 0 | C |
| Example 4A | X-4 | 3 | 2 | A | 5 | 0 | C |
| Example 5A | X-6 | 2 | 3 | A | 5 | 0 | C |
| Example 6A | X-7 | 2 | 3 | A | 5 | 0 | C |
| Example 7A | X-8 | 2 | 3 | A | 5 | 0 | C |
| Example 8A | X-9 | 2 | 3 | A | 5 | 0 | C |
| Example 9A | X-11 | 2.5 | 2.5 | A | 5 | 0 | C |
| Example | X-12 | 2.5 | 2.5 | A | 5 | 0 | C |
| 10A | | | | | | | |
| Example | X-13 | 2.5 | 2.5 | A | 5 | 0 | C |
| 11A | | | | | | | |
| Example | X-14 | 2.5 | 2.5 | A | 5 | 0 | C |
| 12A | | | | | | | |
| Example | X-15 | 2.5 | 2.5 | A | 5 | 0 | C |
| 13A | | | | | | | |
| Example | X-16 | 3.5 | 1.5 | B | 5 | 0 | C |
| 14A | | | | | | | |
| Example | X-17 | 4 | 1 | B | 5 | 0 | C |
| 15A | | | | | | | |
| Comparative | R-1 | 5 | 0 | C | 5 | 0 | C |
| Example 1A | | | | | | | |
| Comparative | R-2 | 2.6 | 2.4 | A | 2.7 | 2.3 | A |
| Example 2A | | | | | | | |

TABLE 3

| | | Ru Layer | | | TEOS layer | | |
|---|---|---|---|---|---|---|---|
| | | Film | ALD | | Film | ALD | |
| | | formation | Inhibition | | formation | Inhibition | |
| | Chemical | amount | amount | | amount | amount | |
| | liquid | (nm) | (nm) | Evaluation | (nm) | (nm) | Evaluation |
| Example 1B | X-1 | 3.4 | 1.6 | B | 5 | 0 | C |
| Example 2B | X-2 | 2.3 | 2.7 | A | 5 | 0 | C |
| Example 3B | X-3 | 2.5 | 2.5 | A | 5 | 0 | C |
| Example 4B | X-4 | 2.9 | 2.1 | A | 5 | 0 | C |
| Example 5B | X-5 | 2 | 3 | A | 5 | 0 | C |
| Example 6B | X-6 | 2 | 3 | A | 5 | 0 | C |
| Example 7B | X-7 | 2.1 | 2.9 | A | 5 | 0 | C |
| Example 8B | X-8 | 2.1 | 2.9 | A | 5 | 0 | C |
| Example 9B | X-9 | 2.3 | 2.7 | A | 5 | 0 | C |
| Example | X-11 | 2.1 | 2.9 | A | 5 | 0 | C |
| 10B | | | | | | | |
| Example | X-12 | 2.1 | 2.9 | A | 5 | 0 | C |
| 11B | | | | | | | |
| Example | X-13 | 2.2 | 2.8 | A | 5 | 0 | C |
| 12B | | | | | | | |
| Example | X-14 | 2.2 | 2.8 | A | 5 | 0 | C |
| 13B | | | | | | | |
| Example | X-15 | 2.1 | 2.9 | A | 5 | 0 | C |
| 14B | | | | | | | |
| Example | X-16 | 3.4 | 1.6 | B | 5 | 0 | C |
| 15B | | | | | | | |
| Example | X-17 | 3.9 | 1.1 | B | 5 | 0 | C |
| 16B | | | | | | | |
| Comparative | R-1 | 5 | 0 | C | 5 | 0 | C |
| Example 1B | | | | | | | |
| Comparative | R-2 | 2.5 | 2.5 | A | 2.7 | 2.3 | A |
| Example 2B | | | | | | | |

TABLE 4

| | | TiN Layer | | | TEOS layer | | |
|---|---|---|---|---|---|---|---|
| | | Film | ALD | | Film | ALD | |
| | | formation | Inhibition | | formation | Inhibition | |
| | Chemical | amount | amount | | amount | amount | |
| | liquid | (nm) | (nm) | Evaluation | (nm) | (nm) | Evaluation |
| Example 1C | X-1 | 3.3 | 1.7 | B | 5 | 0 | C |
| Example 2C | X-2 | 2.1 | 2.9 | A | 5 | 0 | C |
| Example 3C | X-3 | 2.5 | 2.5 | A | 5 | 0 | C |
| Example 4C | X-4 | 2.9 | 2.1 | A | 5 | 0 | C |
| Example 5C | X-6 | 2.1 | 2.9 | A | 5 | 0 | C |
| Example 6C | X-7 | 2.2 | 2.8 | A | 5 | 0 | C |
| Example 7C | X-8 | 2.2 | 2.8 | A | 5 | 0 | C |
| Example 8C | X-9 | 2.2 | 2.8 | A | 5 | 0 | C |
| Example 9C | X-11 | 2.4 | 2.6 | A | 5 | 0 | C |
| Example 10C | X-12 | 2 | 3 | A | 5 | 0 | C |
| Example 11C | X-13 | 2.1 | 2.9 | A | 5 | 0 | C |
| Example 12C | X-14 | 2.3 | 2.7 | A | 5 | 0 | C |
| Example 13C | X-15 | 2.3 | 2.7 | A | 5 | 0 | C |
| Example 14C | X-16 | 3.3 | 1.7 | B | 5 | 0 | C |
| Example 15C | X-17 | 3.9 | 1.1 | B | 5 | 0 | C |
| Comparative | R-1 | 5 | 0 | C | 5 | 0 | C |
| Example 1C | | | | | | | |
| Comparative | R-2 | 2.3 | 2.7 | A | 2.7 | 2.3 | A |
| Example 2C | | | | | | | |

TABLE 5

| | | TEOS layer | | | Si Layer | | |
|---|---|---|---|---|---|---|---|
| | | Film | ALD | | Film | ALD | |
| | | formation | Inhibition | | formation | Inhibition | |
| | Chemical | amount | amount | | amount | amount | |
| | liquid | (nm) | (nm) | Evaluation | (nm) | (nm) | Evaluation |
| Example | X-10 | 2.5 | 2.5 | A | 5 | 0 | C |
| 1D | | | | | | | |

In Table 2, in Examples 1A to 15A in which the chemical liquid used in the production method of the embodiment of the present invention was used, the evaluation of the ALD inhibition amount for the W layer wafer was A or B, and the evaluation of the ALD inhibition amount for the TEOS layer wafer was C. From these results, it is found that since the first coating film was formed on the W layer whereas the first coating film was not formed on the TEOS layer, the ALD coating film was inhibited from being formed on the W layer by the first coating film and the ALD coating film was formed on the TEOS layer without such inhibition in a case where the ALD treatment was performed.

Therefore, it is considered that in a case where the modified substrate is produced according to the production method of the embodiment of the present invention, using a substrate having a W layer as the first surface and a TEOS layer as the second surface, a substrate in which an ALD coating film is formed on the TEOS layer with good selectivity can be obtained.

The same as in Examples 1A to 15A applies to Examples 1B to 16B in which the Ru layer and the TEOS layer were evaluated, Examples 1C to 15C in which the TiN layer and the TEOS layer were evaluated, and Example 1D in which the TEOS layer and the Si layer were evaluated.

In Comparative Example 1A in which the specific compound was not used, the evaluation of the ALD inhibition amount was C in both the W layer and the TEOS layer, as compared with the evaluation in Examples. That is, in Comparative Example 1A, since the coating film as in Examples was not formed on both the W layer and the TEOS layer, the ALD coating film was formed on both the W layer and the TEOS layer. Therefore, in a case where the above-described steps 1 and 2 are carried out using a chemical liquid of R-1 with a substrate having a W layer as the first surface and a TEOS layer as the second surface, ALD coating films are formed on both the first surface and the second surface, and therefore, a desired effect cannot be obtained.

In addition, in Comparative Example 2A, the evaluation of the ALD inhibition amount was A in both the W layer and the TEOS layer. That is, in Comparative Example 2A, the coating films as in Examples were formed on both the W layer and the TEOS layer, and the ALD coating film was not easily formed on both the W layer and the TEOS layer. Therefore, in a case where the above-described steps 1 and 2 are carried out using a substrate having a W layer as the first surface and a TEOS layer as the second surface, and the chemical liquid for R-2, the formation of the ALD coating films on both the first surface and the second surface are suppressed, and thus, a desired effect cannot be obtained.

In Comparative Examples 1B and 2B and Comparative Examples 1C and 2C, the same tendency as described above was also observed.

In addition, from the comparison of Examples 1A to 13A, it was confirmed that in a case where the crosslinkable group in the specific compound 1 or the specific compound 2 is a styryl group or a vinyl group, the effect of the present invention is more excellent.

From the comparison between Examples 6A to 8A and Examples 14A and 15A, it was confirmed that the effect of the present invention was more excellent in a case where the specific compound 1 or the specific compound 2 had a divalent aliphatic hydrocarbon group having 6 to 18 carbon atoms, which may have an etheric oxygen atom.

In addition, it could be confirmed that in a case where a substrate (substrate 1) having a surface of at least one of the W layer, the Ru layer, or the TiN layer as the first surface and having a TEOS layer as the second surface was brought into contact with each of the chemical liquids shown in Table 1, and then subjected to the same procedure of the ALD treatment as the ALD treatment carried out in the section of [ALD Inhibitory Properties], a substrate 1 in which an ALD coating film is formed on the TEOS layer with good selectivity can be obtained with the same tendency as the evaluation results shown in Tables 2 to 4.

In addition, it was confirmed that in a case where a substrate (substrate 2) having a TEOS layer as the first surface and an Si layer as the second surface was used instead of the substrate 1 and the chemical liquid shown in Table 1 was used, a substrate 2 in which an ALD coating film was formed on the Si layer with good selectivity could be obtained with the same tendency as the evaluation results shown in Table 5.

### [Evaluation B]

The ALD inhibitory properties and the chemical liquid stability were evaluated for Examples 101 to 132.

### [ALD Inhibitory Properties]

The ALD inhibitory properties were evaluated for the W layer wafer and the TEOS layer wafer, using chemical liquids Y-1 to Y-32 having compositions which will be described later. The ALD inhibitory properties were evaluated by the same procedure as in [ALD Inhibitory Properties].

### [Evaluation of Chemical Liquid Stability]

The chemical liquid stability was evaluated according to the following procedure, using chemical liquids Y-1 to Y-32 having the compositions which will be described later.

Each chemical liquid was stored under a condition of 45° C. for one month and the turbidity was measured. The turbidity was measured using an integrating sphere type turbidimeter PT-200 manufactured by Mitsubishi Chemical Analytech Co., Ltd.

From the measured turbidity, the chemical liquid stability was evaluated according to the following evaluation standard. It can be said that the smaller the turbidity, the better the chemical liquid stability.

### —Evaluation Standard—

A: The turbidity was less than 0.1 ppm.
B: The turbidity was 0.1 ppm or more.

### [Results]

The evaluation results of the ALD inhibitory properties and the chemical liquid stability of Examples 101 to 132 are shown in Tables 6 to 9 below.

The chemical liquids Y-1 to Y-32 used in each Example were prepared by mixing each polymerization inhibitor having a content (parts by mass) shown in Tables 6 to 9 with 100 parts by mass of each specific compound, and then adding the solvent S-1 thereto such that the concentration of solid contents was 0.1% by mass. The solid content refers to the specific compound and the polymerization inhibitor.

In Tables 6 to 9, the names of each polymerization inhibitor used for the preparation of the chemical liquid are as follows. Furthermore, the structures or names of the specific compounds and the solvent S-1 used in the preparation of the chemical liquid are as described above in [Evaluation A].

### <Polymerization Inhibitor>

D-1: 4-Methoxyphenol
D-2: N-Nitroso-N-phenylhydroxylamine aluminum
D-3: Poly(4-methacryloyloxy-2,2,6,6-tetramethylpiperidin-N-oxyl)
D-4: 4-tert-Butylcatechol
D-5: 1,4-Benzoquinone
D-6: Phenothiazine
D-7: N,N-Diethylhydroxylamine
D-8: 4-Hydroxy-2,2,6,6-tetramethylpiperidine 1-oxyl
D-9: Cupferron
D-10: 2,4-Bis(octylthiomethyl)-6-methylphenol

In Tables 6 to 9, a description separated by “/” in the column of “Type” indicates that a plurality of compounds are included as the substance, and a description separated by “/” in the column of “Content” shows the contents of the plurality of compounds in order. For example, the “Polymerization inhibitor” of Example 128 includes “D-1” and “D-5”, with contents of “0.01” and “0.01” parts by mass, respectively.

TABLE 6

| | Example | 101 | 102 | 103 | 104 | 105 | 106 | 107 | 108 | 109 | 110 |
|---|---|---|---|---|---|---|---|---|---|---|---|
| Chemical liquid | | Y-1 | Y-2 | Y-3 | Y-4 | Y-5 | Y-6 | Y-7 | Y-8 | Y-9 | Y-10 |
| Specific | Type | A-1 | A-2 | A-3 | A-4 | A-6 | A-7 | A-8 | A-9 | A-11 | A-12 |
| compound | Content | 100 | 100 | 100 | 100 | 100 | 100 | 100 | 100 | 100 | 100 |
| | (parts by mass) | | | | | | | | | | |
| Polymerization | Type | D-1 | D-1 | D-1 | D-1 | D-1 | D-1 | D-1 | D-1 | D-1 | D-1 |
| inhibitor | Content | 0.02 | 0.02 | 0.02 | 0.02 | 0.02 | 0.02 | 0.02 | 0.02 | 0.02 | 0.02 |
| | (parts by mass) | | | | | | | | | | |
| Solution stability | | A | A | A | A | A | A | A | A | A | A |
| Evaluation of | Film formation | 3.5 | 2.6 | 3 | 3 | 2 | 2 | 2 | 2 | 2.5 | 2.5 |
| W layer | amount | | | | | | | | | | |
| | (nm) | | | | | | | | | | |
| | ALD Inhibition | 1.5 | 2.4 | 2 | 2 | 3 | 3 | 3 | 3 | 2.5 | 2.5 |
| | amount | | | | | | | | | | |
| | (nm) | | | | | | | | | | |
| | Evaluation | B | A | A | A | A | A | A | A | A | A |
| Evaluation of | Film formation | 5 | 5 | 5 | 5 | 5 | 5 | 5 | 5 | 5 | 5 |
| TEOS layer | amount | | | | | | | | | | |
| | (nm) | | | | | | | | | | |
| | ALD Inhibition | 0 | 0 | 0 | 0 | 0 | 0 | 0 | 0 | 0 | 0 |
| | amount | | | | | | | | | | |
| | (nm) | | | | | | | | | | |
| | Evaluation | C | C | C | C | C | C | C | C | C | C |

TABLE 7

| | Example | 111 | 112 | 113 | 114 | 115 | 116 | 117 | 118 |
|---|---|---|---|---|---|---|---|---|---|
| Chemical liquid | | Y-11 | Y-12 | Y-13 | Y-14 | Y-15 | Y-16 | Y-17 | Y-18 |
| Specific | Type | A-1 | A-1 | A-1 | A-1 | A-1 | A-1 | A-1 | A-1 |
| compound | Content | 100 | 100 | 100 | 100 | 100 | 100 | 100 | 100 |
| | (parts by mass) | | | | | | | | |
| Polymerization | Type | D-2 | D-3 | D-4 | D-5 | D-6 | D-7 | D-8 | D-9 |
| inhibitor | Content | 0.02 | 0.02 | 0.02 | 0.02 | 0.02 | 0.02 | 0.02 | 0.02 |
| | (parts by mass) | | | | | | | | |
| Solution stability | | A | A | A | A | A | A | A | A |
| Evaluation of | Film formation | 3.5 | 3.5 | 3.5 | 3.5 | 3.5 | 3.5 | 3.5 | 3.5 |
| W layer | amount | | | | | | | | |
| | (nm) | | | | | | | | |
| | ALD Inhibition | 1.5 | 1.5 | 1.5 | 1.5 | 1.5 | 1.5 | 1.5 | 1.5 |
| | amount | | | | | | | | |
| | (nm) | | | | | | | | |
| | Evaluation | B | B | B | B | B | B | B | B |
| Evaluation of | Film formation | 5 | 5 | 5 | 5 | 5 | 5 | 5 | 5 |
| TEOS layer | amount | | | | | | | | |
| | (nm) | | | | | | | | |
| | ALD Inhibition | 0 | 0 | 0 | 0 | 0 | 0 | 0 | 0 |
| | amount | | | | | | | | |
| | (nm) | | | | | | | | |
| | Evaluation | C | C | C | C | C | C | C | C |

TABLE 8

| | Example | 119 | 120 | 121 | 122 | 123 | 124 | 125 | 126 |
|---|---|---|---|---|---|---|---|---|---|
| Chemical liquid | | Y-19 | Y-20 | Y-21 | Y-22 | Y-23 | Y-24 | Y-25 | Y-26 |
| Specific | Type | A-3 | A-4 | A-8 | A-9 | A-3 | A-4 | A-8 | A-9 |
| compound | Content | 100 | 100 | 100 | 100 | 100 | 100 | 100 | 100 |
| | (parts by mass) | | | | | | | | |
| Polymerization | Type | D-5 | D-5 | D-5 | D-5 | D-8 | D-8 | D-8 | D-8 |
| inhibitor | Content | 0.02 | 0.02 | 0.02 | 0.02 | 0.02 | 0.02 | 0.02 | 0.02 |
| | (parts by mass) | | | | | | | | |
| Solution stability | | A | A | A | A | A | A | A | A |
| Evaluation of | Film formation | 3 | 3 | 2 | 2 | 3 | 3 | 2 | 2 |
| W layer | amount | | | | | | | | |
| | (nm) | | | | | | | | |
| | ALD Inhibition | 2 | 2 | 3 | 3 | 2 | 2 | 3 | 3 |
| | amount | | | | | | | | |
| | (nm) | | | | | | | | |
| | Evaluation | A | A | A | A | A | A | A | A |
| Evaluation of | Film formation | 5 | 5 | 5 | 5 | 5 | 5 | 5 | 5 |
| TEOS layer | amount | | | | | | | | |
| | (nm) | | | | | | | | |
| | ALD Inhibition | 0 | 0 | 0 | 0 | 0 | 0 | 0 | 0 |
| | amount | | | | | | | | |
| | (nm) | | | | | | | | |
| | Evaluation | C | C | C | C | C | C | C | C |

TABLE 9

| | Example | 127 | 128 | 129 | 130 | 131 | 132 |
|---|---|---|---|---|---|---|---|
| Chemical liquid | | Y-27 | Y-28 | Y-29 | Y-30 | Y-31 | Y-32 |
| Specific | Type | A-1 | A-3 | A-4 | A-8 | A-1 | A-1 |
| compound | Content | 100 | 100 | 100 | 100 | 100 | 100 |
| | (parts by mass) | | | | | | |
| Polymerization | Type | D-1/D-5 | D-1/D-9 | D-1/D-10 | D-1/D-8 | D-1 | D-1 |
| inhibitor | Content | 0.01/0.01 | 0.01/0.01 | 0.01/0.01 | 0.01/0.01 | 0.9 | 0.005 |
| | (parts by mass) | | | | | | |
| Solution stability | | A | A | A | A | A | A |
| Evaluation of | Film formation | 3.5 | 3 | 3 | 2 | 3.5 | 3.5 |
| W layer | amount | | | | | | |
| | (nm) | | | | | | |
| | ALD Inhibition | 1.5 | 2 | 2 | 3 | 1.5 | 1.5 |
| | amount | | | | | | |
| | (nm) | | | | | | |
| | Evaluation | B | A | A | A | B | B |
| Evaluation of | Film formation | 5 | 5 | 5 | 5 | 5 | 5 |
| TEOS layer | amount (nm) | | | | | | |
| | ALD Inhibition | 0 | 0 | 0 | 0 | 0 | 0 |
| | amount | | | | | | |
| | (nm) | | | | | | |
| | Evaluation | C | C | C | C | C | C |

From the results of Tables 6 to 9, it was confirmed that in the methods for producing modified substrates of Examples 101 to 132, the ALD coating film formation was inhibited by the first coating film layer in the W layer, the ALD coating film was formed in the TEOS layer without such inhibition, and the ALD coating film could be formed with good selectivity, similar to Examples 1A to 15A.

### [Evaluation C]

According to the following procedure, a substrate in which a first coating film was formed on a substrate consisting of only a first surface was prepared using chemical liquids described in Tables 10 to 13 which will be described later, and the ALD inhibitory properties were evaluated.

### [Manufacture of Sample Substrate for Evaluation (Method for Forming First Coating Film)]

First, a commercially available silicon wafer (diameter of 12 inches) was prepared as a substrate, and a copper (Cu) layer, a cobalt (Co) layer, a silicon oxycarbide (SiOC) layer, a tungsten (W) layer, a ruthenium (Ru) layer, and a molybdenum (Mo) layer were each formed on one surface of the silicon wafer to prepare a Cu layer wafer, a Co layer wafer, an SiOC layer wafer, a W layer wafer, an Ru layer wafer, and a Mo layer wafer (hereinafter also collectively referred to as “wafers with layers”).

Furthermore, the Cu layer and the Co layer were formed by a sputtering method, the SiOC layer was formed by a plasma chemical vapor deposition (CVD) method, and the W layer, the Ru layer, and the Mo layer were formed by a CVD method.

The film forming conditions were adjusted so that the thickness of each layer was 20 nm.

Subsequently, a sample in which a first coating film was formed on each wafer was produced for each of the silicon wafer and the wafer with a layer prepared by the procedure, using the chemical liquids shown in Tables 10 to 13. As a specific procedure, a sample was manufactured according to the procedure described in [Manufacture of Sample Substrate for Evaluation (Method for Forming First Coating Film)] in the evaluation A.

### [ALD Inhibitory Properties]

Using an atomic layer deposition device (Flex-AL manufactured by Oxford Instruments plc), a titanium nitride layer (ALD coating film) was formed on the sample (sample for evaluation) obtained in [Manufacture of Sample Substrate for Evaluation (Method for Forming First Coating Film)] and the sample in a case where the first coating film was not formed (untreated sample). Tetrakis(dimethylamino) titanium (TDMAT) was used as an organometallic raw material and ammonia was used as a reducing agent.

Furthermore, the ALD treatment temperature was set to 300° C., and the ALD treatment was performed on each sample under a condition that the film thickness was 5 nm with respect to each sample in a case where the first coating film was not formed (untreated sample).

The film thickness of the ALD coating film in the sample after the ALD treatment was measured using an X-ray fluorescence analysis (XRF) device (AZX400 manufactured by Rigaku Corporation). The film thickness of the ALD coating film was measured at five points of the sample and an average value thereof was taken as the film thickness.

The value obtained according to the following Expression (A) was evaluated for an ALD inhibition amount (nm) according to the following standard. The larger the ALD inhibition amount (nm), the more difficult it is for the coating film to be deposited by the ALD treatment.

ALD inhibition amount (nm)=(Film thickness (5 nm) of ALD coating film of untreated sample)−(Film thickness (nm) of ALD coating film of sample for evaluation) Expression (A):

### (Evaluation Standard)

A: The ALD inhibition amount is 2.0 nm or more.
B: The ALD inhibition amount is 1.0 nm or more and less than 2.0 nm.
C: The ALD inhibition amount is less than 1.0 nm.

### [Results]

The components used for the preparation of the chemical liquid and content ratios (mass ratios) thereof are shown in Tables 10 to 13 which will be described later. Furthermore, as a component not described in the tables, any chemical liquid includes 100 ppm by mass of 4-hydroxy-2,2,6,6-tetramethylpiperidine 1-oxyl as a polymerization inhibitor.

In Tables 10 to 13, the column of “Mw” shows the molecular weights of the specific compounds.

In addition, the evaluation results of the ALD inhibitory properties are shown in Tables 14 to 17.

Furthermore, the results assuming that a surface consisting of at least one of the Cu layer or the Co layer was used as the first surface and a surface consisting of at least one of the SiOx (silicon wafer) layer or the SiOC layer was used as the second surface are shown in Tables 14 and 16.

The results of a case where a surface consisting of at least one of the W layer, the Ru layer, or the Mo layer is used as the first surface and a surface consisting of at least one of the SiOx (silicon wafer) layer or the SiOC layer is used as the second surface are shown in Tables 15 and 17.

TABLE 10

| | No. | Structural formula | Mw | xx-1 | Xx-2 | xx-3 | xx-4 | xx-5 | xx-6 | xx-7 | xx-8 | xx-9 | xx-10 | xx-11 | zz-1 |
|---|---|---|---|---|---|---|---|---|---|---|---|---|---|---|---|
| Specific com- pound | x-1 | 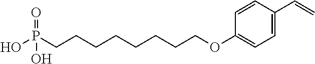 [SMILES: C=Cc1ccc(OCCCCCCCCP(=O)(O)O)cc1] | 312.35 | 0.05 | | | | | | | | | | | |
| | x-2 | 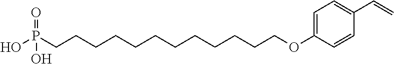 [SMILES: C=Cc1ccc(OCCCCCCCCCCCCP(=O)(O)O)cc1] | 368.45 | | 0.05 | | | | | | | 0.01 | 0.5 | 0.05 | |
| | x-3 | 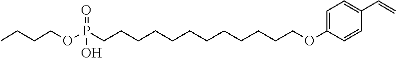 [SMILES: C=Cc1ccc(OCCCCCCCCCCCCP(=O)(O)OCCCC)cc1] | 424.56 | | | 0.05 | | | | | | | | | |
| | x-4 | 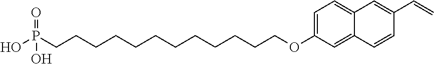 [SMILES: C=Cc1ccc2cc(OCCCCCCCCCCCCP(=O)(O)O)ccc2c1] | 418.51 | | | | 0.05 | | | | | | | | |
| | x-5 | 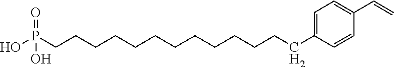 [SMILES: C=Cc1ccc(CCCCCCCCCCCCCP(=O)(O)O)cc1] | 366.48 | | | | | 0.05 | | | | | | | |
| | x-6 | 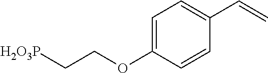 | 228.18 | | | | | | 0.05 | | | | | | |
| | x-7 | 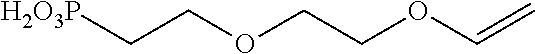 | 193.14 | | | | | | | 0.05 | | | | | |
| | x-8 | 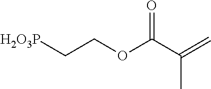 | 194.12 | | | | | | | | 0.05 | | | | |
| Com- para- tive com- | z-1 | 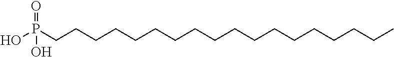 [SMILES: CCCCCCCCCCCCCCCCCCP(=O)(O)O] | 334.48 | | | | | | | | | | | | 0.05 |
| pound | | | | | | | | | | | | | | | |

| | | | | | | | | | | | | | |
|---|---|---|---|---|---|---|---|---|---|---|---|---|---|
| Solvent | S-1 | 99.95 | 99.95 | 99.95 | 99.95 | 99.95 | 99.95 | 99.95 | 99.95 | 99.99 | 99.5 | | 99.95 |
| | S-2 | | | | | | | | | | | 99.95 | |

| | | | | | | | | | | | | |
|---|---|---|---|---|---|---|---|---|---|---|---|---|
| total | 100 | 100 | 100 | 100 | 100 | 100 | 100 | 100 | 100 | 100 | 100 | 100 |

TABLE 11

| | No. | Structural formula | Mw | yy-1 | yy-2 | yy-3 | yy-4 | yy-5 | yy-6 | yy-7 | yy-8 | yy-9 | yy-10 | yy-11 | yy-12 | yy-13 | yy-14 | zzzz-1 |
|---|---|---|---|---|---|---|---|---|---|---|---|---|---|---|---|---|---|---|
| Spe- cific com- po- und | y- 1 | 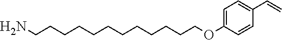 [SMILES: C=Cc1ccc(OCCCCCCCCCCCCN)cc1] | 303.49 | 0.05 | | | | | | | | | | | 0.01 | 0.5 | 0.05 | |
| | y- 2 | 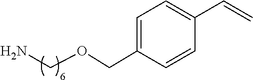 | 233.36 | | 0.05 | | | | | | | | | | | | | |
| | y- 3 | 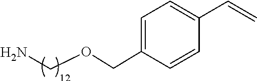 | 317.52 | | | 0.05 | | | | | | | | | | | | |
| | y- 4 | 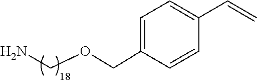 | 373.63 | | | | 0.05 | | | | | | | | | | | |
| | y- 5 | 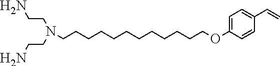 [SMILES: C=Cc1ccc(OCCCCCCCCCCCCN(CCN)CCN)cc1] | 389.63 | | | | | 0.05 | | | | | | | | | | |
| | y- 6 | 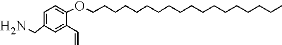 [SMILES: C=Cc1cc(CN)ccc1OCCCCCCCCCCCCCCCCCC] | 401.68 | | | | | | 0.05 | | | | | | | | | |
| | y- 7 | 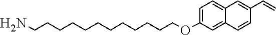 [SMILES: C=Cc1ccc2cc(OCCCCCCCCCCCCN)ccc2c1] | 353.55 | | | | | | | 0.05 | | | | | | | | |
| | y- 8 | 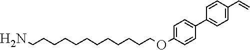 [SMILES: C=Cc1ccc(-c2ccc(OCCCCCCCCCCCCN)cc2)cc1] | 379.59 | | | | | | | | 0.05 | | | | | | | |
| | y- 9 | 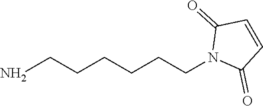 [SMILES: NCCCCCCN1C(=O)C=CC1=O] | 196.25 | | | | | | | | | 0.05 | | | | | | |
| | y- 10 | 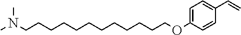 [SMILES: C=Cc1ccc(OCCCCCCCCCCCCN(C)C)cc1] | 331.54 | | | | | | | | | | 0.05 | | | | | |
| | y- 11 | 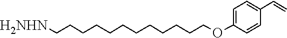 | 316.51 | | | | | | | | | | | 0.05 | | | | |
| Com- para- | zzz- 1 | 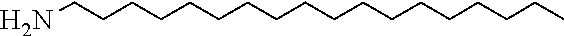 [SMILES: CCCCCCCCCCCCCCCCCCN] | 269.52 | | | | | | | | | | | | | | | 0.05 |
| tive | | | | | | | | | | | | | | | | | | |
| com- | | | | | | | | | | | | | | | | | | |
| po- | | | | | | | | | | | | | | | | | | |
| und | | | | | | | | | | | | | | | | | | |

| | | | | | | | | | | | | | | | | |
|---|---|---|---|---|---|---|---|---|---|---|---|---|---|---|---|---|
| Sol- | S-1 | 99.95 | 99.95 | 99.95 | 99.95 | 99.95 | 99.95 | 99.95 | 99.95 | 99.95 | 99.95 | 99.95 | 99.95 | 99.5 | | 99.95 |
| vent | S-2 | | | | | | | | | | | | | | 99.95 | |

| | | | | | | | | | | | | | | | |
|---|---|---|---|---|---|---|---|---|---|---|---|---|---|---|---|
| total | 100 | 100 | 100 | 100 | 100 | 100 | 100 | 100 | 100 | 100 | 100 | 100 | 100 | 100 | 100 |

TABLE 12

| | Name of structural formula of compound | | Mw | xx-12 | xx-13 | xx-14 | xx-15 | xx-16 |
|---|---|---|---|---|---|---|---|---|
| Specific com- pound | x-1 | 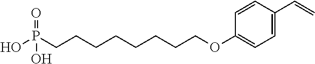 [SMILES: C=Cc1ccc(OCCCCCCCCP(=O)(O)O)cc1] | 312.35 | 0.02 | 0.02 | 0.02 | 0.02 | 0.02 |
| | x-2 | 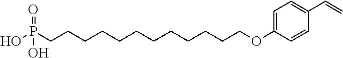 [SMILES: C=Cc1ccc(OCCCCCCCCCCCCP(=O)(O)O)cc1] | 368.45 | | | | | |
| | x-5 | 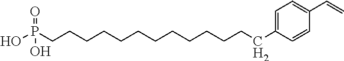 [SMILES: C=Cc1ccc(CCCCCCCCCCCCCP(=O)(O)O)cc1] | 366.48 | | | | | |
| Com- para- tive com- | z-1 | 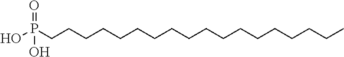 [SMILES: CCCCCCCCCCCCCCCCCCP(=O)(O)O] | 334.48 | | | | | |
| pound | | | | | | | | |

| | | | | | | | |
|---|---|---|---|---|---|---|---|
| Solvent | S-1 | Propylene glycol monomethyl ether | 80 | | | | |
| | S-3 | γ-Butyrolactone | | 80 | | | |
| | S-4 | Ethyl lactate | | | 80 | | |
| | S-5 | Isopropyl alcohol | | | | 80 | |
| | S-6 | Propylene carbonate | | | | | 80 |
| | S-7 | Ultrapure water | 20 | 20 | 20 | 20 | 20 |

| | | | | | |
|---|---|---|---|---|---|
| total | 100.02 | 100.02 | 100.02 | 100.02 | 100.02 |

TABLE 13

| | Name of | | | | | | | |
|---|---|---|---|---|---|---|---|---|
| (Continued) | compound | xx-17 | xx-18 | xx-19 | xx-20 | xx-21 | xx-22 | zz-2 |
| Specific | x-1 | 0.02 | | | 0.02 | 0.02 | 0.02 | |
| compound | x-2 | | 0.02 | | | | | |
| | x-5 | | | 0.02 | | | | |
| Comparative | z-1 | | | | | | | 0.02 |
| compound | | | | | | | | |
| Solvent | S-1 | | 80 | 80 | 40 | 40 | | 80 |
| | S-3 | 20 | | | 40 | | 40 | |
| | S-4 | | | | | | | |
| | S-5 | | | | | | | |
| | S-6 | | | | | 40 | 40 | |
| | S-7 | 80 | 20 | 20 | 20 | 20 | 20 | 20 |

| | | | | | | | |
|---|---|---|---|---|---|---|---|
| total | 100.02 | 100.02 | 100.02 | 100.02 | 100.02 | 100.02 | 100.02 |

TABLE 14

| | Name or structural formula of compound | | Mw | yy-15 | yy-16 | yy-17 | yy-18 | yy-19 |
|---|---|---|---|---|---|---|---|---|
| Specific com- pound | y-2 | 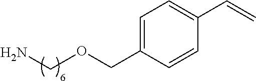 | 233.36 | 0.02 | 0.02 | 0.02 | 0.02 | 0.02 |
| | y-1 | 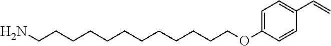 [SMILES: C=Cc1ccc(OCCCCCCCCCCCCN)cc1] | 303.49 | | | | | |
| Com- para- | zzz-1 | 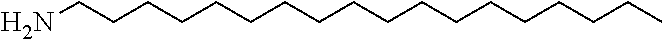 [SMILES: CCCCCCCCCCCCCCCCCCN] | 269.52 | | | | | |
| tive | | | | | | | | |
| com- | | | | | | | | |
| pound | | | | | | | | |

| | | | | | | | |
|---|---|---|---|---|---|---|---|
| Solvent | S-1 | Propylene glycol monomethyl ether | 80 | | | | |
| | S-3 | y-Butyrolactone | | 80 | | | |
| | S-4 | Ethyl lactate | | | 80 | | |
| | S-5 | Isopropyl alcohol | | | | 80 | |
| | S-6 | Propylene carbonate | | | | | 80 |
| | S-7 | Ultrapure water | 20 | 20 | 20 | 20 | 20 |

| | | | | | |
|---|---|---|---|---|---|
| total | 100.02 | 100.02 | 100.02 | 100.02 | 100.02 |

TABLE 15

| | Name of | | | | | | |
|---|---|---|---|---|---|---|---|
| (Continued) | compound | yy-20 | yy-21 | yy-22 | yy-23 | yy-24 | zzzz-2 |
| Specific | y-2 | 0.02 | | 0.02 | 0.02 | 0.02 | |
| compound | y-1 | | 0.02 | | | | |
| Comparative | zzz-1 | | | | | | 0.02 |
| compound | | | | | | | |
| Solvent | S-1 | | 80 | 40 | 40 | | 80 |
| | S-3 | 20 | | 40 | | 40 | |
| | S-4 | | | | | | |
| | S-5 | | | | | | |
| | S-6 | | | | 40 | 40 | |
| | S-7 | 80 | 20 | 20 | 20 | 20 | 20 |

| | | | | | | |
|---|---|---|---|---|---|---|
| total | 100.02 | 100.02 | 100.02 | 100.02 | 100.02 | 100.02 |

TABLE 16

| | | Cu | | Co | | SiOx | | SiOC | |
|---|---|---|---|---|---|---|---|---|---|
| | | ALD | | ALD | | ALD | | ALD | |
| | | Inhibition | | Inhibition | | Inhibition | | Inhibition | |
| | Chemical | amount | | amount | | amount | | amount | |
| Example | liquid | (nm) | Evaluation | (nm) | Evaluation | (nm) | Evaluation | (nm) | Evaluation |
| Example X-1 | xx-1 | 4.5 | A | 4.2 | A | 0 | C | 0 | C |
| Example X-2 | xx-2 | 5 | A | 5 | A | 0 | C | 0 | C |
| Example X-3 | xx-3 | 3 | A | 2.9 | A | 0 | C | 0 | C |
| Example X-4 | xx-4 | 5 | A | 5 | A | 0 | C | 0 | C |
| Example X-5 | xx-5 | 5 | A | 5 | A | 0 | C | 0 | C |
| Example X-6 | xx-6 | 1.9 | B | 1.8 | B | 0 | C | 0 | C |
| Example X-7 | xx-7 | 1.7 | B | 1.6 | B | 0 | C | 0 | C |
| Example X-8 | xx-8 | 1.5 | B | 1.4 | B | 0 | C | 0 | C |
| Example X-9 | xx-9 | 5 | A | 5 | A | 0 | C | 0 | C |
| Example X-10 | xx-10 | 5 | A | 5 | A | 0 | C | 0 | C |
| Example X-11 | xx-11 | 5 | A | 5 | A | 0 | C | 0 | C |
| Comparative | zz-1 | 0 | C | 0 | C | 0 | C | 0 | C |
| Example Z-1 | | | | | | | | | |

TABLE 17

| | | W | | Ru | | Mo | | SiOx | | SiOC | |
|---|---|---|---|---|---|---|---|---|---|---|---|
| | | ALD | | ALD | | ALD | | ALD | | ALD | |
| | | Inhibition | | Inhibition | | Inhibition | | Inhibition | | Inhibition | |
| | Chemical | amount | | amount | | amount | | amount | | amount | |
| Example | liquid | (nm) | Evaluation | (nm) | Evaluation | (nm) | Evaluation | (nm) | Evaluation | (nm) | Evaluation |
| Example | yy-1 | 5 | A | 5 | A | 5 | A | 0 | C | 0 | C |
| Y-1 | | | | | | | | | | | |
| Example | yy-2 | 3.5 | A | 3.4 | A | 3.3 | A | 0 | C | 0 | C |
| Y-2 | | | | | | | | | | | |
| Example | yy-3 | 4 | A | 4.1 | A | 4.1 | A | 0 | C | 0 | C |
| Y-3 | | | | | | | | | | | |
| Example | yy-4 | 4.5 | A | 4.3 | A | 4.2 | A | 0 | C | 0 | C |
| Y-4 | | | | | | | | | | | |
| Example | yy-5 | 4.7 | A | 4.2 | A | 4.6 | A | 0 | C | 0 | C |
| Y-5 | | | | | | | | | | | |
| Example | yy-6 | 3.2 | A | 3.7 | A | 3.1 | A | 0 | C | 0 | C |
| Y-6 | | | | | | | | | | | |
| Example | yy-7 | 5 | A | 5 | A | 5 | A | 0 | C | 0 | C |
| Y-7 | | | | | | | | | | | |
| Example | yy-8 | 5 | A | 5 | A | 5 | A | 0 | C | 0 | C |
| Y-8 | | | | | | | | | | | |
| Example | yy-9 | 1.8 | B | 1.3 | B | 1.5 | B | 0 | C | 0 | C |
| Y-9 | | | | | | | | | | | |
| Example | yy-10 | 1.5 | B | 1.1 | B | 1.3 | B | 0 | C | 0 | C |
| Y-10 | | | | | | | | | | | |
| Example | yy-11 | 1.1 | B | 1.1 | B | 1.2 | B | 0 | C | 0 | C |
| Y-11 | | | | | | | | | | | |
| Example | yy-12 | 5 | A | 5 | A | 5 | A | 0 | C | 0 | C |
| Y-12 | | | | | | | | | | | |
| Example | yy-13 | 5 | A | 5 | A | 5 | A | 0 | C | 0 | C |
| Y-13 | | | | | | | | | | | |
| Example | yy-14 | 5 | A | 5 | A | 5 | A | 0 | C | 0 | C |
| Y-14 | | | | | | | | | | | |
| Comparative | zzzz-1 | 0 | C | 0 | C | 0 | C | 0 | C | 0 | C |
| Example | | | | | | | | | | | |
| ZZ-1 | | | | | | | | | | | |

TABLE 18

| | | Cu | | Co | | SiOx | | SiOC | |
|---|---|---|---|---|---|---|---|---|---|
| | | ALD | | ALD | | ALD | | ALD | |
| | | Inhibition | | Inhibition | | Inhibition | | Inhibition | |
| | Chemical | amount | | amount | | amount | | amount | |
| Example | liquid | (nm) | Evaluation | (nm) | Evaluation | (nm) | Evaluation | (nm) | Evaluation |
| Example X-12 | xx-12 | 4.5 | A | 4.2 | A | 0 | C | 0 | C |
| Example X-13 | xx-13 | 5 | A | 5 | A | 0 | C | 0 | C |
| Example X-14 | xx-14 | 3 | A | 2.9 | A | 0 | C | 0 | C |
| Example X-15 | xx-15 | 3.1 | A | 3.5 | A | 0 | C | 0 | C |
| Example X-16 | xx-16 | 5 | A | 5 | A | 0 | C | 0 | C |
| Example X-17 | xx-17 | 1.4 | B | 1.2 | B | 0 | C | 0 | C |
| Example X-18 | xx-18 | 5 | A | 4.7 | A | 0 | C | 0 | C |
| Example X-19 | xx-19 | 5 | A | 5 | A | 0 | C | 0 | C |
| Example X-20 | xx-20 | 5 | A | 5 | A | 0 | C | 0 | C |
| Example X-21 | xx-21 | 5 | A | 5 | A | 0 | C | 0 | C |
| Example X-22 | xx-22 | 5 | A | 5 | A | 0 | C | 0 | C |
| Comparative | zz-2 | 0 | C | 0 | C | 0 | C | 0 | C |
| Example Z-2 | | | | | | | | | |

TABLE 19

| | | W | | Ru | | Mo | | SiOx | | SiOC | |
|---|---|---|---|---|---|---|---|---|---|---|---|
| | | ALD | | ALD | | ALD | | ALD | | ALD | |
| | | Inhibition | | Inhibition | | Inhibition | | Inhibition | | Inhibition | |
| | Chemical | amount | | amount | | amount | | amount | | amount | |
| Example | liquid | (nm) | Evaluation | (nm) | Evaluation | (nm) | Evaluation | (nm) | Evaluation | (nm) | Evaluation |
| Example Y-15 | yy-15 | 5 | A | 4.8 | A | 4.2 | A | 0 | C | 0 | C |
| Example Y-16 | yy-16 | 4.4 | A | 4.7 | A | 3.9 | A | 0 | C | 0 | C |
| Example Y-17 | yy-17 | 4 | A | 4.4 | A | 4.1 | A | 0 | C | 0 | C |
| Example Y-18 | yy-18 | 4.5 | A | 4.5 | A | 4 | A | 0 | C | 0 | C |
| Example Y-19 | yy-19 | 4.7 | A | 4.1 | A | 3.8 | A | 0 | C | 0 | C |
| Example Y-20 | yy-20 | 1.9 | B | 1.7 | B | 1.1 | B | 0 | C | 0 | C |
| Example Y-21 | yy-21 | 4.3 | A | 4 | A | 3.7 | A | 0 | C | 0 | C |
| Example Y-22 | yy-22 | 4.1 | A | 3.9 | A | 4.1 | A | 0 | C | 0 | C |
| Example Y-23 | yy-23 | 4 | A | 3.8 | A | 4.3 | A | 0 | C | 0 | C |
| Example Y-24 | yy-24 | 4.9 | A | 4.6 | A | 4.6 | A | 0 | C | 0 | C |
| Comparative | zzzz-2 | 0 | C | 0 | C | 0 | C | 0 | C | 0 | C |
| Example ZZ-2 | | | | | | | | | | | |

As shown in the tables, it has been confirmed that according to the method for producing a modified substrate of the embodiment of the present invention, it is possible to produce a modified substrate in which an ALD coating film is formed in a predetermined region with good selectivity by performing an ALD treatment.

In addition, from the comparison of Examples Y-1 to Y-9, it was confirmed that in a case where the crosslinkable group in the specific compound 1 or the specific compound 2 is a styryl group, a vinylnaphthyl group, or a vinyl group, the effect of the present invention is more excellent.

From the comparison between Examples X-1 to X-5 and Examples X-6 to X-8, it was confirmed that the effect of the present invention is further improved in a case where the specific compound 1 or the specific compound 2 has a divalent aliphatic hydrocarbon group having 6 to 18 carbon atoms, which may have an etheric oxygen atom.

From the comparison between Examples Y-1 to Y-8 and Examples Y-10 and Y-11, it was confirmed that in a case where the specific compound 1 or the specific compound 2 has a primary amino group, the effect of the present invention is more excellent.

From the comparison of Examples X-12 to X-22, the comparison of Examples Y-15 to Y-24, and the like, it was confirmed that the effect of the present invention was more excellent in a case where the content of water was less than 80% by mass with respect to the total mass of the solvent.

In addition, it was confirmed that even in a case where a tantalum nitride layer was formed on each sample for evaluation by using pentakis (dimethylamino) tantalum (PDMAT) instead of TDMAT in the step of [ALD Inhibitory Properties], and the ALD inhibition amount was evaluated according to the procedure shown in [ALD Inhibitory Properties], the same results as those in Tables 14 to 17 were obtained.

What is claimed is:

1. A method for producing a modified substrate, the method comprising:
a step 1 of bringing a substrate having at least two surfaces of a first surface and a second surface, which are composed of materials different from each other, into contact with a chemical liquid including a compound which has a functional group bonded to or adsorbed on the first surface, and a crosslinkable group, and has a molecular weight of 500 or less, and a solvent, to form a first coating film on the first surface; and
a step 2 of subjecting the substrate obtained in the step 1 to an atomic layer deposition treatment to form a second coating film on the second surface.

2. The method for producing a modified substrate according to claim 1,
wherein the functional group bonded to or adsorbed on the first surface is selected from the group consisting of a nitrogen-containing group, a phosphonic acid group or a salt thereof, a phosphonic acid ester, a phosphoric acid group or a salt thereof, a carboxy group or a salt thereof, a hydroxy group, a thiol group, and a hydrolyzable silyl group.

3. The method for producing a modified substrate according to claim 1,
wherein the crosslinkable group is an ethylenically unsaturated group.

4. The method for producing a modified substrate according to claim 1,
wherein the crosslinkable group is selected from the group consisting of an acryloyl group, a methacryloyl group, a vinyl ether group, a styryl group, a vinylnaphthyl group, and a vinyl group.

5. A method for producing a modified substrate, the method comprising:
a step 1 of bringing a substrate having at least two surfaces of a first surface and a second surface, which are composed of materials different from each other, into contact with a chemical liquid including a compound which has a group selected from the group consisting of a nitrogen-containing group, a phosphonic acid group or a salt thereof, a phosphonic acid ester, a phosphoric acid group or a salt thereof, a carboxy group or a salt thereof, a hydroxy group, a thiol group, and a hydrolyzable silyl group, and a crosslinkable group, and has a molecular weight of 500 or less, and a solvent, to form a first coating film on the first surface; and
a step 2 of subjecting the substrate obtained in the step 1 to an atomic layer deposition treatment to form a second coating film on the second surface.

6. The method for producing a modified substrate according to claim 5,
wherein the crosslinkable group is an ethylenically unsaturated group.

7. The method for producing a modified substrate according to claim 5,
wherein the crosslinkable group is selected from the group consisting of an acryloyl group, a methacryloyl group, a vinyl ether group, a styryl group, a vinylnaphthyl group, and a vinyl group.

8. The method for producing a modified substrate according to claim 1,
wherein at least one of the first surface or the second surface is a metal surface composed of a metal.

9. The method for producing a modified substrate according to claim 1,
wherein at least one of the first surface or the second surface includes at least one metal atom selected from the group consisting of a copper atom, a cobalt atom, a titanium atom, a tantalum atom, a tungsten atom, a ruthenium atom, and a molybdenum atom.

10. The method for producing a modified substrate according to claim 9,
wherein at least one of the first surface or the second surface includes at least one metal atom selected from the group consisting of a titanium atom, a tungsten atom, a ruthenium atom, and a molybdenum atom.

11. The method for producing a modified substrate according to claim 1,
wherein the second coating film is a metal film or a metal oxide film.

12. The method for producing a modified substrate according to claim 1, the method further comprising:
a step 3 of removing the first coating film after the step 2.

13. The method for producing a modified substrate according to claim 1,
wherein the chemical liquid includes a polymerization inhibitor.

14. The method for producing a modified substrate according to claim 13,
wherein the polymerization inhibitor includes at least one compound selected from the group consisting of a phenol-based compound, a quinone-based compound, a free radical-based compound, an amine-based compound, and a phosphine-based compound.

15. The method for producing a modified substrate according to claim 13,
wherein a content of the polymerization inhibitor is 0.001 to 1.000 part by mass with respect to 100 parts by mass of the compound.

16. The method for producing a modified substrate according to claim 13,
wherein a content of the polymerization inhibitor is 0.01 parts by mass or more with respect to 100 parts by mass of the compound.

17. The method for producing a modified substrate according to claim 5,
wherein the chemical liquid includes a polymerization inhibitor.

18. The method for producing a modified substrate according to claim 17,
wherein the polymerization inhibitor includes at least one compound selected from the group consisting of a phenol-based compound, a quinone-based compound, a free radical-based compound, an amine-based compound, and a phosphine-based compound.

19. The method for producing a modified substrate according to claim 17,
wherein a content of the polymerization inhibitor is 0.001 to 1.000 part by mass with respect to 100 parts by mass of the compound.

20. The method for producing a modified substrate according to claim 17,
wherein a content of the polymerization inhibitor is 0.01 parts by mass or more with respect to 100 parts by mass of the compound.

21. The method for producing a modified substrate according to claim 1,
wherein the chemical liquid includes water.

22. The method for producing a modified substrate according to claim 21,
wherein a content of the water is 80% by mass or less with respect to a total mass of the solvent.

23. The method for producing a modified substrate according to claim 1,
wherein the chemical liquid includes three or more kinds of the solvents.

24. A method for producing a semiconductor device, the method comprising:
the method for producing a modified substrate according to claim 1.
